(19) United States
(12) Patent Application Publication
(10) Pub. No.: US 2026/0245524 A1
(43) Pub. Date: Aug. 20, 2026

(54) GATE DRIVER, DISPLAY DEVICE INCLUDING GATE DRIVER, AND ELECTRONIC DEVICE INCLUDING DISPLAY DEVICE

(71) Applicant: Samsung Display Co., Ltd., Yongin-Si (KR)

(72) Inventors: Yoonsup KIM, Yongin-si (KR); Jung-Taek KIM, Yongin-si (KR)

(21) Appl. No.: 19/391,553

(22) Filed: Nov. 17, 2025

(30) Foreign Application Priority Data
Feb. 17, 2025 (KR) 10-2025-0020301

(51) Int. Cl. G09G 3/3266; G09G 3/20; G09G 3/3233; G11C 19/28

(52) U.S. Cl. CPC G09G 3/3266; G09G 3/2092; G09G 3/3233; G09G 2300/0842; G09G 2310/0286; G09G 2320/0257; G09G 2320/043; G11C 19/28

(57) ABSTRACT

A display device includes a display panel divided into regions each of which includes at least one gate line and pixels connected to the at least one gate line, a timing controller receiving a mode selecting signal for indicating a driving mode of the display device, and generating a gate clock signal and a gate control signal based on the mode selecting signal, and a gate driver generating sensing line selecting signals corresponding to the regions based on the gate clock signal and the gate control signal, and generating scan carry signals and sensing carry signals corresponding to the regions based on the sensing line selecting signals. The gate driver provides the scan carry signals and the sensing carry signals to the at least one gate line during a blank period of a frame.

### CROSS-REFERENCE TO RELATED APPLICATION

This application claims priority to and the benefit of Korean Patent Application No. 10-2025-0020301 filed on February 17, 2025 in the Korean Intellectual Property Office, the entire contents of which are incorporated herein by reference.

### BACKGROUND

### a. Field of the Invention

The present disclosure relates to a gate driver, a display device including the gate driver, and an electronic device including the display device.

### b. Description of the Related Art

A gate driver of a display device may sequentially provide gate signals to pixels of a display panel on a row-by-row basis. The gate driver may be implemented in the form of a shift register which includes a plurality of stages to sequentially provide gate signals to the pixels. Each stage may charge a control node (or Q node) based on a carry signal from the previous stage and output a gate signal and/or a carry signal based on the voltage of the charged control node, and may discharge the control node based on the carry signal from the next stage.

The time required to acquire sensing data varies depending on frame rates (Hz). However, in an always-on display (AOD) mode, a period for acquiring sensing data becomes longer as the frame rate decreases. When the period for acquiring sensing data becomes longer, the temperature or mobility characteristics of the panel may change. Accordingly, image quality artifacts such as flickering or malfunction in the panel protection function may occur due to discrepancies between the sensing data and the actual state of the panel. The discrepancies may also affect after-image compensation based on temperature and display luminance, thereby shortening the product lifespan. To prevent these problems, it is necessary to reduce the sensing data acquisition period even when the display panel is operated in a low frequency.

### SUMMARY OF THE INVENTION

The present disclosure provides a gate driver for reducing an acquisition period of sensing data in a low electric power mode.

According to an embodiment of the present disclosure, a display device includes a display panel divided into a plurality of regions, each of the plurality of regions including at least one gate line and a plurality of pixels connected to the at least one gate line, a timing controller configured to receive a mode selecting signal for indicating a driving mode of the display device, and generating a gate clock signal and a gate control signal based on the mode selecting signal, and a gate driver configured to generate a plurality of sensing line selecting signals corresponding to the plurality of regions based on the gate clock signal and the gate control signal, and generating a plurality of scan carry signals and a plurality of sensing carry signals corresponding to the plurality of region based on the plurality of sensing line selecting signals. The gate driver provides the plurality of scan carry signals and the plurality of sensing carry signals to the at least one gate line during a blank period of a frame.

In an embodiment, each of the plurality of scan carry signals and the plurality of sensing carry signals may include a first scan carry signal and a first sensing carry signal, respectively. The gate driver may generate the first scan carry signal and the first sensing carry signal, and may output the first scan carry signal and the first sensing carry signal to the pixels included in a first region when a first sensing line selecting signal corresponding to the first region has an enable level.

In an embodiment, the gate driver may include a sensing line selecting signal generator configured to generate the plurality of sensing line selecting signals, a clock signal generator configured to generate a plurality of scan carry clock signals, a plurality of sensing carry clock signals, and a plurality of carry clock signals based on the gate clock signal, and a gate signal generator configured to generate the plurality of scan carry signals and the plurality of sensing carry signals based on the plurality of sensing line selecting signal, the plurality of scan carry clock signals, the plurality of sensing carry clock signals, and the plurality of carry clock signals.

In an embodiment, the gate signal generator may include a carry signal generator configured to generate a plurality of carry signals based on the plurality of carry clock signals, a scan carry signal generator configured to generate the plurality of scan carry signals based on the plurality of scan carry clock signals and the plurality of carry signals, a sensing carry signal generator configured to generate the plurality of sensing carry signals based on the plurality of sensing carry clock signals and the plurality of carry signals.

In an embodiment, the gate signal generator may include a plurality of stages corresponding to the plurality of regions and including a first stage which receives a first sensing line selecting signal and corresponding to the first region. When the first sensing line selecting signal has an enable level, the first stage may output a first scan carry signal and a first sensing carry signal to the pixels included in the first region based on the first sensing line selecting signal.

In an embodiment, the first stage may include a scan selecting circuit configured to receive the first sensing line selecting signal, a transmitting signal, and a first carry signal corresponding to the first stage, and control a sensing control node based on the first sensing line selecting signal, the transmitting signal, and the first carry signal, a sensing discharge circuit configured to receive a scan start signal, and control the sensing control node based on the scan start signal, a sensing output circuit configured to receive a sensing carry clock signal among the plurality of sensing carry clock signals, and control a sensing output node based on the sensing carry clock signal, and a scan output circuit configured to receive a scan carry clock signal among the plurality of scan carry clock signals, and control a scan output node based on the scan carry clock signal.

In an embodiment, the scan selecting circuit may charge a sensing node when the first sensing line selecting signal has an enable level and the first carry signal has an enable level, and the scan selecting circuit may transmit a voltage of the sensing node to the sensing control node when the transmitting signal has an enable level.

In an embodiment, the transmitting signal may have the enable level during the blank period for which the display device displays no images.

In an embodiment, the sensing output circuit may control the sensing output node based on the voltage of the sensing control node when the sensing carry clock signal has an enable level.

In an embodiment, the sensing output circuit may output the first sensing carry signal when the voltage of the sensing control node has a high level and the sensing carry clock signal has the enable level.

In an embodiment, the scan output circuit may control the scan output node based on the voltage of the sensing control node when the scan carry clock signal has an enable level.

In an embodiment, the scan output circuit may output the first scan carry signal when the voltage of the sensing control node has a high level and the scan carry clock signal has the enable level.

In an embodiment, the sensing discharge circuit may discharge the sensing control node when the scan start signal has an enable level.

In an embodiment, the driving mode may include a normal mode in which the display device is operated at a high frequency and a low electric power mode in which the display device is operated at a low frequency.

According to an embodiment of the present disclosure, a gate driver includes a sensing line selecting signal generator configured to receive a gate clock signal and a gate control signal, and generate a plurality of sensing line selecting signals corresponding to a plurality of regions based on the gate clock signal and the gate control signal, wherein each of the gate clock signal and the gate control signal is generated based on a mode selecting signal for indicating a driving mode of a display device, and each of the plurality of regions includes at least one gate line, a clock signal generator configured to generate a plurality of scan carry clock signals, a plurality of sensing carry clock signals, and a plurality of carry clock signals based on the gate clock signal, and a gate signal generator configured to generate a plurality of scan carry signals and a plurality of sensing carry signals based on the plurality of sensing line selecting signals, the plurality of scan carry clock signals, the plurality of sensing carry clock signals, and the plurality of carry clock signals, and provide the plurality of scan carry signals and the plurality of sensing carry signals to the at least one gate line during a blank period of a frame.

In an embodiment, the gate signal generator may include a carry signal generator configured to generate a plurality of carry signals based on the plurality of carry clock signals, a scan carry signal generator configured to generate the plurality of scan carry signals based on the plurality of scan carry clock signals and the plurality of carry signals, and a sensing carry signal generator configured to generate the plurality of sensing carry signals based on the plurality of sensing carry clock signals and the plurality of carry signals.

In an embodiment, the gate signal generator may include a plurality of stages corresponding to the plurality of regions and including a first stage, the first stage receiving a first sensing line selecting signal and corresponding to a first region. When the first sensing line selecting signal has an enable level, the first stage may output a first scan carry signal and a first sensing carry signal to the pixels included in the first region based on the first sensing line selecting signal.

In an embodiment, the first stage may include a scan selecting circuit configured to receive the first sensing line selecting signal, a transmitting signal, and a first carry signal corresponding to the first stage, and control a sensing control node based on the first sensing line selecting signal, the transmitting signal, and the first carry signal, a sensing discharge circuit configured to receive a scan start signal, and control the sensing control node based on the scan start signal, a sensing output circuit configured to receive a sensing carry clock signal among the plurality of sensing carry clock signals, and control a sensing output node based on the sensing carry clock signal, and a scan output circuit configured to receive a scan carry clock signal among the plurality of scan carry clock signals, and control a scan output node based on the scan carry clock signal.

According to an embodiment of the present disclosure, an electronic device includes a processor configured to generate a mode selecting signal for indicating a driving mode of a display device, and a display module divided into a plurality of regions, each of the plurality of regions includes at least one gate line and a plurality of pixels connected to the at least one gate line. The display module is configured to generate a gate clock signal and a gate control signal based on the mode selecting signal, generate a plurality of sensing line selecting signals corresponding to the plurality of regions based on the gate clock signal and the gate control signal, generate a plurality of scan carry signals and a plurality of sensing carry signals corresponding to the plurality of regions based on the each of the plurality of sensing line selecting signals. The display module provides the plurality of scan carry signals and the plurality of sensing carry signals to the at least one gate line during a blank period of a frame.

In an embodiment, each of the plurality of scan carry signals and the plurality of sensing carry signals may include a first scan carry signal and a first sensing carry signal respectively. The display module may generate the first scan carry signal and the first sensing carry signal, and may output the first scan carry signal and the first sensing carry signal to the pixels included in a first region when a first sensing line selecting signal corresponding to the first region has an enable level.

### BRIEF DESCRIPTION OF THE DRAWINGS

FIG. 1 shows a display device according to an embodiment.

FIG. 2 shows periods according to driving modes of a display device according to an embodiment.

FIG. 3 shows an equivalent circuit of a pixel according to an embodiment.

FIG. 4 shows a gate driver according to an embodiment.

FIG. 5 shows a portion of a display device according to an embodiment.

FIG. 6 shows a circuit diagram of a stage according to an embodiment.

FIG. 7 shows a circuit diagram illustrating a portion of the stage according to an embodiment.

FIG. 8 shows a timing diagram illustrating an operation of a gate driver according to an embodiment.

FIG. 9 shows a timing diagram illustrating an operation of a gate driver according to an embodiment.

FIG. 10 shows a timing diagram illustrating an operation of a gate driver according to an embodiment.

FIG. 11 shows a timing diagram illustrating an operation of a gate driver according to an embodiment.

FIG. 12 shows a portion of a display device according to an embodiment.

FIG. 13 shows a block diagram of an electronic device according to an embodiment.

FIGS. 14 to FIG. 16 show schematic diagrams illustrating electronic devices according to various embodiments.

### DETAILED DESCRIPTION

In the following detailed description, only certain embodiments of the present disclosure have been shown and described, simply by way of illustration. As those skilled in the art would readily appreciate, the described embodiments may be modified in various different ways without departing from the spirit or scope of the present disclosure.

Parts that are irrelevant to the description will be omitted to clearly describe the present disclosure, and the same elements will be designated by the same reference numerals throughout the specification.

The size and thickness of each configuration shown in the drawings are arbitrarily shown to facilitate understanding and for ease of description, but the present disclosure is not limited thereto. In the drawings, the thickness of layers, films, panels, regions, etc., are enlarged for clarity. To facilitate understanding and for ease of description, the thicknesses of some layers and areas are exaggerated.

It should be understood that when an element such as a layer, film, region, or substrate is referred to as being “on” another element, it may be directly on the other element or intervening elements may also be present. In contrast, when an element is referred to as being “directly on” another element, there are no intervening elements present between the element and another element. Further, in the specification, being "above" or "on" a reference part means being positioned above or below the reference part and does not necessarily mean being positioned "above" or "on" it in the opposite direction of gravity.

Unless explicitly described to the contrary, the word “comprise” and “include,” and their variations such as “comprises,” “comprising,” “includes” or “including,” should be understood to imply the inclusion of stated elements but not the exclusion of any other elements.

Further, throughout the specification, the phrase “in a plan view” means viewing a target portion from the top, and the phrase “in a cross-sectional view” means viewing a cross-section formed by vertically cutting a target portion from the side.

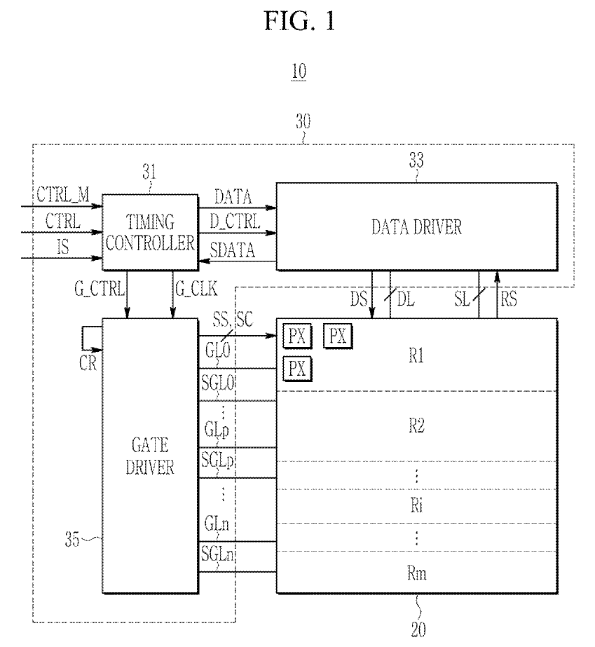

FIG. 1 shows a display device according to an embodiment.

The display device 10 may receive an input image signal (IS) from the host and may display the input image signal (IS). The display device 10 may display two-dimensional 2D or three-dimensional 3D images to a user.

The display device 10 may include a display panel 20 and a display driving circuit 30. In an embodiment, the display device 20 may be a device in which the display driving circuit 30 and the display panel 20 are implemented as a single module. For example, the display driving circuit 30 may be mounted on the substrate of the display panel 20, or the display driving circuit 30 and the display panel 20 may be electrically connected through a connecting member such as a flexible printed circuit board (FPCB).

The display device 10 may perform a display operation.

When the display device 10 performs the display operation, the display device 10 may display an image corresponding to an input image signal (IS) received from a host. When the display device 10 performs the display operation, the display device 10 may compensate image data corresponding to the input image signal (IS) based on sensing data (SDATA).

In an embodiment, the display device 10 may be operated in a plurality of driving modes. For example, the display device 10 may be operated in a normal mode or a low electric power mode for displaying the input image signal (IS).

The normal mode may be a mode for displaying dynamic images. The display device 10 may be driven at a high frequency when operating in the normal mode. For example, when the display device 10 operates in the normal mode, the display device 10 may optimize the screen quality through periodic updates of sensing data, and fully utilize functions such as temperature and after-image compensation, panel protection functions, or etc.. The display device 10 may frequently update sensing data in real time. Although the display device 10 has relatively high power consumption when operating in the normal mode, it may provide high screen quality and reactivity.

The low electric power mode may display still images. For example, the low electric power mode may be an always-on display (AOD) mode. The display device 10 may be driven at low frequency when operating in the low electric power mode. For example, when the display device 10 operates in the low electric power mode, the frame rate may be lowered, and display brightness and pixel driving voltage may be reduced. The display device 10 may also have a longer acquisition period for sensing data. Although the display device 10 is effective in saving energy when operating in the low electric power mode, there may be limitations in reflecting temperature changes or mobility characteristics of the panel in real time.

In an embodiment, the display device 10 may perform a pixel characteristic measuring operation. When the display device 10 performs the pixel characteristic measuring operation, the display device 10 may generate sensing data (SDATA) based on an internal measurement reference voltage. For example, the display device 10 may perform the pixel characteristic measuring operation during a vertical blank period when the display device 10 displays no images. For example, as the characteristics of elements included in a pixel may change over time, the display device 10 may measure pixel characteristics at specific intervals to accurately display the image. For example, the pixel characteristic may be a value of a current output from the pixel in response to the voltage applied to the pixel.

The display panel 20 may display images to the user based on the input image signal (IS) received from the host. The display panel 20 may be one of the display devices that receive electrically transmitted video signals and display 2D images, such as a thin-film-transistor liquid crystal display (TFT LCD), a field emission display, or a plasma display panel (PDP). In an embodiment, the display panel 20 may include pixels implemented using organic light emitting diode (OLED) cells. The OLED cell may receive a data signal (DS) from a data line (DL) and a gate signal from a gate line (GL), and may display images through the operation of the organic light emitting diode (OLED). However, the present disclosure is not limited thereto. For example, the display panel 20 may be implemented as another type of flat panel display or flexible display panel. For example, the display device 10 may include one or more display panels 20.

The display panel 20 may include signal lines—for example, gate lines (GL), data lines (DL), gate sensing lines (SGL), and sensing lines (SL). Additionally, the display panel 20 may include pixels (PX) connected to signal lines and arranged in a matrix format. The display panel 20 may display images based on the data signal (DS) received from a data driver 33 and the gate signal received from a gate driver 35.

The display panel 20 may be divided into regions (R1, R2, …, Ri, …, Rm). In an embodiment, each of the regions (R1, R2, ..., Ri, ..., Rm) may include at least one gate line (GL0, ..., GLp, ..., GLn) and at least one gate sensing line (SGL0, ..., SGLp, ..., SGLn). Each of the regions (R1, R2, …, Ri, …, Rm) may include at least one pixel (PX).

The display driving circuit 30 may generate analog signals for driving the display panel 20 based on the input image signal (IS) received from the host. For example, the analog signals may include gate signals and data signals driving the pixels included in the display panel 20. The display driving circuit 30 may provide gate signals and data signals to the pixels. The display panel 20 may emit light corresponding to the input image signal (IS) based on the data signal provided from a data driver 33.

In an embodiment, the display driving circuit 30 may include a timing controller 31, the data driver 33, and the gate driver 35.

The timing controller 31 may control driving of the display driving circuit 30 based on control instructions (CTRL) received from the host. The timing controller 31 may perform various types of image processing, such as changing the format of image data and reducing power consumption, on the input image signal (IS) received from the host.

The timing controller 31 may control the driving of the display driving circuit 30 based on a mode selecting signal (CTRL_M) received from the host. The mode selecting signal (CTRL_M) may indicate a driving mode in which the display device 10 operates among a plurality of driving modes. For example, the mode selecting signal (CTRL_M) may include a signal which drives the display device 10 to operate in either the normal mode or low electric power mode.

The timing controller 31 may generate a data control signal (D_CTRL) based on the control instruction (CTRL) and the input image signal (IS). The timing controller 31 may generate image data (DATA) based on the input image signal (IS). The timing controller 31 may transmit the data control signal (D_CTRL) and the image data (DATA) to the data driver 33.

In an embodiment, the timing controller 31 may compensate for the data voltage that the data driver 33 applies to the display panel 20 based on the characteristics of each of the pixels. Here, the characteristics of the pixels may be the value of the output current in response to the voltage applied to the pixel. However, the characteristics of the pixels are not limited to this. For example, the characteristics of the pixels may be a value of the output voltage in response to the voltage applied to the pixels. For example, the characteristics of the pixels may be information indicating degrees of degradation of the pixels, such as information on the degradation of the organic light emitting diode (OLED) or the transistors included in the pixels.

In an embodiment, the timing controller 31 may store a measurement reference voltage required to perform a pixel characteristic measuring operation. The timing controller 31 may generate image data (DATA) based on the measurement reference voltage when the display device 10 performs a pixel characteristic measuring operation.

The timing controller 31 may receive sensing data (SDATA) from the data driver 33. The sensing data (SDATA) may be a signal representing the electric characteristics of each pixel (PX) or the plurality of pixels (PX) provided on the display panel 20. In an embodiment, the timing controller 31 may store the sensing data (SDATA) received from the data driver 33. The timing controller 31 may transmit the sensing data (SDATA) corresponding to the input image signal (IS) to the data driver 33 as the data control signal (D_CTRL). The timing controller 31 may compensate the data voltage applied by the data driver 33 to the display panel 20 based on the characteristics of the selected pixels received from the data driver 33.

The timing controller 31 may generate a gate control signal (G_CTRL) and a gate clock signal (G_CLK) based on the control instruction (CTRL), the mode selecting signal (CTRL_M) and the input image signal (IS). The timing controller 31 may transmit the gate control signal (G_CTRL) and the gate clock signal (G_CLK) to the gate driver 35.

The data driver 33 may apply a data signal corresponding to the input image signal (IS) to the display panel 20 in response to the control of the timing controller 31.

In an embodiment, the data driver 33 may measure the characteristics of the pixels. Specifically, the data driver 33 may apply a data signal (DS) corresponding to a predetermined measurement reference voltage to a selected pixel among a plurality of pixels on the display panel 20. The data driver 33 may receive a return signal (RS) in response to the data signal (DS) corresponding to the predetermined measurement reference voltage from the selected pixel. Hereinafter, the “selected pixel” may refer to a portion of the plurality of pixels (PX) on the display panel 20, or an entire pixels (PX) on the display panel 20.

In an embodiment, the data driver 33 may measure the characteristics of the selected pixel based on the data signal (DS) and the return signal (RS). For example, the data driver 33 may obtain a pixel current output from the selected pixel in response to the data signal applied to the selected pixel. The data driver 33 may transmit the characteristics of the selected pixel to the timing controller 31.

The data driver 33 may receive the data control signal (D_CTRL) and the image data (DATA) from the timing controller 31. In an embodiment, the data driver 33 may receive image data (DATA) in units corresponding to the pixels (PX) arranged in the same horizontal line of the display panel 20 at a time. The image data (DATA) may include gray information corresponding to each pixel (PX) to display image corresponding to the input image signal (IS) on the display panel 20. The data driver 33 may process image data (DATA) in synchronization with the clock signal received from the timing controller 31.

In an embodiment, the data driver 33 may apply the data signal (DS) corresponding to a predetermined reference measurement voltage to the selected pixels (PX) through the data lines (DL), and may measure the electric characteristics of the pixels (PX) based on the return signal (RS) received from the pixels (PX) through the sensing lines (SL). For example, the return signal (RS) may be the output current output from the pixels (PX).

The data driver 33 may generate sensing data (SDATA) based on the return signal (RS). The data driver 33 may transmit the sensing data (SDATA) to the timing controller 31.

The gate driver 35 may provide gate voltages to a plurality of pixels (PX) of the display panel 20 through the gate lines (GL) of the display panel 20. In an embodiment, the gate driver 35 may generate a gate voltage to drive the plurality of pixels (PX) based on the gate control signal (G_CTRL) and the gate clock signal (G_CLK), and provide the gate voltage to the plurality of pixels (PX) through each of the gate lines (GL). Specifically, the gate driver 35 may provide pulses of a gate-on voltage to the corresponding gate line (GL) during the corresponding driving period based on the gate control signal (G_CTRL) and the gate clock signal (G_CLK).

The gate driver 35 may provide a sensing voltage to each of the selected pixels (PX) on the display panel 20 through a plurality of gate sensing lines (SGL) based on the gate control signal (G_CTRL) and the gate clock signal (G_CLK). Specifically, the gate driver 35 may provide pulses of a sensing-on voltage to the selected pixels (PX) through the corresponding gate sensing line (SGL) during the corresponding driving period based on the gate control signal (G_CTRL). The gate driver 35 may output the gate control signal (G_CTRL) to the display panel 20 through the gate sensing lines (SGL).

In an embodiment, the gate driver 35 may generate a carry signal (CR), a sensing carry signal (SC), and a scan carry signal (SS) based on the gate control signal (G_CTRL) and the gate clock signal (G_CLK). In an embodiment, the gate driver 35 may generate a sensing carry signal (SC) and a scan carry signal (SS) based on the carry signal (CR). In an embodiment, the gate driver 35 may transmit the sensing carry signal (SC) and the scan carry signal (SS) to the display panel 20.

FIG. 1 shows that the gate driver 35 is connected to the display panel 20 through n-numbered gate lines (GL) and n-numbered sensing lines (SL), but the present disclosure is not limited thereto. For example, the display driving circuit 30 may include a different number of gate sensing lines (SGL) from the number of gate lines (GLs).

FIG. 1 shows that a pixel (PX) is connected to the data line (DL), the gate line (GL), the gate sensing line (SGL), and the sensing line (SL), but the connection structure of the signal lines of the pixel (PX) of the display device according to an embodiment is not limited thereto. For example, various signal lines may be additionally connected corresponding pixels (PX).

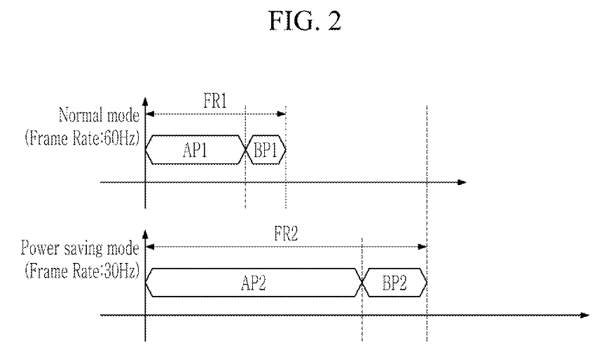

FIG. 2 shows periods according to driving modes of a display device according to an embodiment.

When the display device 10 operates in the normal mode, it may be driven at a first frame frequency. In addition, the display device 10 may be driven at a second frame frequency when operating in the low electric power mode.

FIG. 2 shows a first frame FR1 when the display device 10 operates in the normal mode, and a second frame FR2 when the display device 10 operates in the low electric power mode.

The first frame frequency may be different from the second frame frequency. For example, the second frame frequency may be less than the first frame frequency. Therefore, the duration of the second frame FR2 may be longer than the duration of the first frame FR1. That is, the period of the first frame FR1 may be shorter than the period of the second frame FR2. For example, the first frame frequency of the first frame FR1 may be 60 Hz, and the second frame frequency of the second frame FR2 may be 30 Hz.

The first frame FR1 may include a first active period AP1 and a first blank period BP1. The second frame FR2 may include a second active period AP2 and a second blank period BP2. For example, the first active period AP1 may have the shorter duration than the second active period AP2. Additionally, the first blank period BP1 may have the shorter duration than the second blank period BP2.

The display device 10 may control the pixels (PX) to emit light corresponding to the image signal (IS) during the active periods AP1 and AP2. The display device 10 may measure the sensing data (SDATA) during the blank periods BP1 and BP2. When the display device 10 operates in the normal mode, the display device 10 may measure the sensing data (SDATA) at the first period, but when the display device 10 operates in the low electric power mode, the display device 10 may measure the sensing data (SDATA) at the second period, which is longer than the first period. As the period for acquiring sensing data (SDATA) becomes longer, discrepancies between the actual characteristics of the display panel 20 and the characteristics of the display panel 20 indicated by the sensing data (SDATA) may occur.

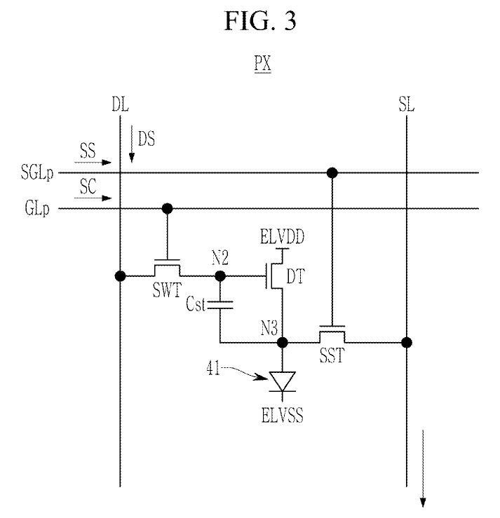

FIG. 3 shows an equivalent circuit of a pixel according to an embodiment.

Specifically, FIG. 3 shows an arbitrary pixel (PX) in the display panel 20 of FIG. 1. The pixel (PX) may include a switching transistor (SWT), a driving transistor (DT), an organic light emitting diode (OLED) 41, a storage capacitor (Cst), and a sensing transistor (SST). The switching transistor (SWT), the driving transistor (DT), the storage capacitor (Cst), and the sensing transistor (SST) may be either a PMOS transistor or an NMOS transistor. To facilitate understanding and for ease of explanation, FIG. 3 shows a case where all the three transistors in the pixel (PX) are NMOS transistors. The switching transistor (SWT), the sensing transistor (SST), and the driving transistor (DT) may include amorphous silicon (a-Si) thin-film transistor (TFT), poly-silicon (poly-Si) TFT, an oxide TFT, or an organic TFT.

A first driving voltage (ELVDD) and a second driving voltage (ELVSS) may be supplied to the pixel (PX). The first driving voltage (ELVDD) may have relatively higher level than the second driving voltage (ELVSS).

The pixel (PX) may be connected to the corresponding gate line (GLp), the data line (DL), the gate sensing line (SGLp), and the sensing line (SL).

The switching transistor (SWT) may be connected to the gate line (GLp) and the data line (DL). The switching transistor (SWT) may be controlled by a gate signal applied through the gate line (GLp). For example, the switching transistor (SWT) may be turned on in response to the sensing carry signal (SC) having a gate-on voltage. The turned-on switching transistor (SWT) may provide the data signal (DS) supplied through the data line (DL) to a gate node N2 of the driving transistor (DT).

The sensing transistor (SST) may be connected to the gate sensing line (SGL) and the sensing line (SL), and may be controlled by the sensing voltage supplied through the gate sensing line (SGLp). For example, the sensing transistor (SST) may be turned on in response to the scan carry signal (SS) having a gate-on voltage. The turned-on sensing transistor (SST) may supply an initialization voltage to a source node N3 of the driving transistor (DT). During the sensing period when the display device 10 measures the sensing data (SDATA), the turned-on sensing transistor (SST) may transmit the voltage of the source node N3 or the driving current of the driving transistor (DT) to the sensing line (SL).

The storage capacitor (Cst) may store the difference between the data voltage applied to the gate node N2 of the driving transistor (DT) through the switching transistor (SWT) and the initialization voltage supplied to the source node N3 of the driving transistor (DT) through the sensing transistor (SST), thereby supplying a constant driving voltage (e.g., the gate-source voltage of the driving transistor (DT)) to the driving transistor (DT) for a predetermined period—for example, one frame.

The first driving voltage (ELVDD) may be applied to a drain node of the driving transistor (DT), and the driving transistor (DT) may supply a driving current, that is proportional to the driving voltage - that is, the difference between the voltage at the gate node N1 and the voltage at the source node N3 of the driving transistor (DT) -, to the OLED 41.

The OLED 41 may include an anode connected to the source node N3 of the driving transistor (DT), a cathode to which the second driving voltage (ELVSS) is supplied, and an organic light emitting layer between the cathode and the anode. The cathode may be a common electrode shared by a plurality of pixels (PX). When the driving current is supplied from the driving transistor (DT), light may be emitted from the organic light emitting layer of the OLED 41. The intensity of light may be proportional to the driving current.

During the emission period (which corresponds to the active period AP1, AP2 in FIG. 2) when the display device 10 emits light corresponding to the image signal (IS), the switching transistor (SWT) may supply the data signal (DS) applied through the data line (DL) to the driving transistor (DT). At this time, the sensing transistor (SST) may be turned on in response to the gate-on voltage supplied through the gate sensing line (SGLp). The difference between the voltage of the gate node N2 and the voltage of the source node N3 of the driving transistor (DT) - that is, the driving current proportional to the driving voltage - may flow to the OLED 41. The OLED 41 may emit light corresponding to the driving current.

During the sensing period (which corresponds to the blank period BP1, BP2 in FIG. 2), the timing controller 31 may determine the pixel (PX) as a selected pixel for measuring the characteristic of the pixel. The switching transistor (SWT) may supply the data signal (DS) corresponding to the measurement reference voltage applied through the data line (DL) to the driving transistor (DT). During the sensing period, the sensing transistor (SST) in the selected pixel (PX) may be turned on in response to the sensing voltage having a gate-on voltage. Hence, the sensing transistor (SST) may output the voltage of the source node N3 or the driving current provided from the driving transistor (DT) or the OLED 41 to the sensing line (SL).

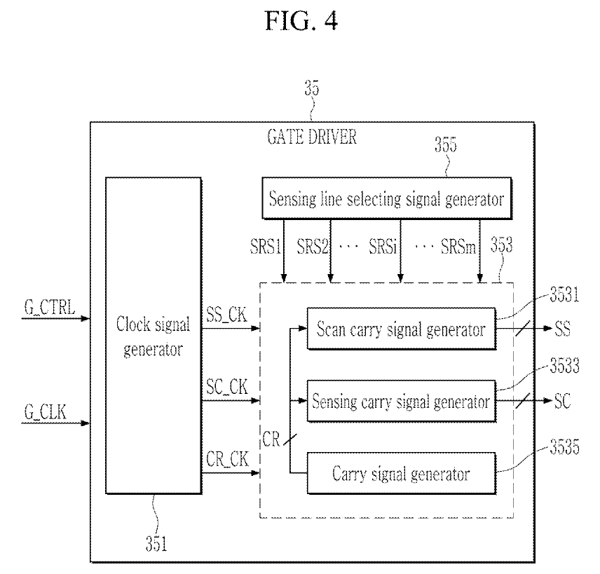

FIG. 4 shows a gate driver according to an embodiment.

As shown in FIG. 4, the gate driver 35 may include a clock signal generator 351, a gate signal generator 353, and a sensing line selecting signal generator 355.

The clock signal generator 351 may generate a scan carry clock signal (SS_CK), the sensing carry clock signal (SC_CK), and a carry clock signal (CR_CK) based on a gate clock signal (G_CLK).

The clock signal generator 351 may transmit the scan carry clock signal (SS_CK), the sensing carry clock signal (SC_CK), and the carry clock signal (CR_CK) to the gate signal generator 353.

The gate signal generator 353 may generate the scan carry signal (SS) and the sensing carry signal (SC) based on the sensing line selecting signals (SRS1, SRS2, ..., SRSi, ..., SRSm), the scan carry clock signal (SS_CK), the sensing carry clock signal (SC_CK), and the carry clock signal (CR_CK).

In an embodiment, the gate signal generator 353 may include a scan carry signal generator 3531, a sensing carry signal generator 3533, and a carry signal generator 3535.

The carry signal generator 3535 may generate a carry signal (CR) based on the carry clock signal (CR_CK). The carry signal generator 3535 may transmit the carry signal (CR) to the scan carry signal generator 3531 and the sensing carry signal generator 3533.

The scan carry signal generator 3531 may generate a scan carry signal (SS) based on the scan carry clock signal (SS_CK) and the carry signal (CR). The scan carry signal generator 3531 may output the scan carry signal (SS) to the display panel 20.

The sensing carry signal generator 3533 may generate a sensing carry signal (SC) based on the sensing carry clock signal (SC_CK) and the carry signal (CR). The sensing carry signal generator 3533 may output the sensing carry signal (SC) to the display panel 20.

The sensing line selecting signal generator 355 may generate sensing line selecting signals (SRS1, SRS2, …, SRSi, …, SRSm) for selecting a sensing line to be measured from among the sensing lines (SL). Each of the sensing line selecting signals (SRS1, SRS2, …, SRSi, …, SRSm) may have either a gate- on voltage (or an enable voltage level) or a gate-off voltage (or a disable voltage level).

The sensing line selecting signal generator 355 may generate a sensing line selecting signal corresponding to a sensing line to be measured from to have the gate-on voltage (or the enable voltage level) based on the gate clock signal (G_CLK) and the gate control signal (G_CTRL).

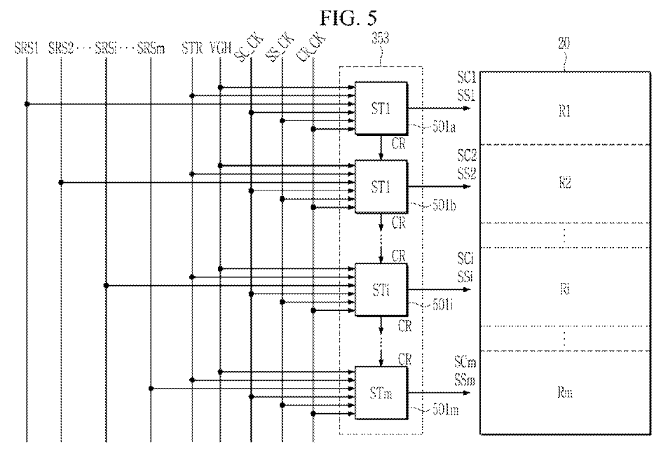

FIG. 5 shows a portion of a display device according to an embodiment.

As shown in FIG. 5, the gate signal generator 353 may include a plurality of stages (501a, 501b, …, 501i, …, 501m). Each of the stages (501a, 501b, …, 501i, …, 501m) may include a scan carry signal generator, a sensing carry signal generator, and a carry signal generator.

Each of the stages (501a, 501b, …, 501i, …, 501m) may correspond to each of the regions (R1, R2, …, Ri, …, Rm).

Although not shown in FIG. 5, the sensing line selecting signal generator 355 in FIG. 4 may select a target stage to be activated among the plurality of stages, and may control the sensing line selecting signal (SRS1, SRS2, …, SRSi, …, SRSm) corresponding to the target stage to have the gate-on voltage (or the enable voltage level).

Each of the stages (501a, 501b, …, 501i, …, 501m) may receive a corresponding sensing line selecting signal from the sensing line selecting signal generator 355. For example, the i-th stage 501i may receive the i-th sensing line selecting signal (SRSi) from the sensing line selecting signal generator 355. Each of the stages (501a, 501b, …, 501i, …, 501m) may receive the scan carry clock signal (SS_CK), the sensing carry clock signal (SC_CK), and the carry clock signal (CR_CK) from the clock signal generator 351. Each of the stages (501a, 501b, …, 501i, …, 501m) may receive a transmitting signal (STR) and a high gate voltage (VGH).

For example, when the i-th stage 501i is the target stage, the sensing line selecting signal generator 355 may generate the i-th sensing line selecting signal (SRSi) corresponding to the i-th stage 501i. The i-th stage 501i may generate a scan carry signal (SSi) and a sensing carry signal (SCi) based on the sensing line selecting signal (SRSi) having an enable level. For example, the i-th stage 501i may generate a scan carry signal (SSi) and a sensing carry signal (SCi) based on the sensing line selecting signal (SRSi), the transmitting signal (STR), the high gate voltage (VGH), and a previous carry signal (CRi-1). The scan carry signal (SSi) and the sensing carry signal (SCi) may be transmitted to the corresponding region (Ri) among the plurality of regions (R1, R2, …, Ri, …, Rm).

Although not shown in FIG. 5, the first stage 501a may charge a control node based on a scan start signal, may charge a gate output node and a carry output node based on a voltage of the charged control node and the clock signals (SS_CK, SC_CK, and CR_CK), and may discharge the control node based on the previous carry signal.

In an embodiment, the control nodes of the respective stages (501a, 501b, …, 501i, …, 501m) of the gate driver 35 may include a scan control node and a sensing control node.

For example, the i-th stage 501i may charge the scan control node based on the scan carry signal (SS) of the i-th stage, and may charge the sensing control node based on the i-th sensing carry signal (SC).

The i-th stage 501i may charge the gate output node and the carry output node based on the voltage of the charged control node and the corresponding clock signal. The gate output node may include a scan output node and a sensing output node. For example, the i-th stage 501i may charge the scan output node based on the voltage of the charged scan control node and the scan clock signal (SS_CK), may charge the sensing output node based on the voltage of the charged sensing control node and the sensing clock signal (SC_CK). The carry output node may include a scan carry output node and a sensing carry output node. For example, the i-th stage 501i may charge the scan carry output node based on the voltage of the charged scan control node and the carry clock signal (CR_CK), and may charge the sensing carry output node based on the voltage of the charged sensing control node and the carry clock signal (CR_CK).

The i-th stage 501i may discharge the gate output node and the carry output node of the i-th stage 501i based on the carry signal from (i+2)-th stage. For example, the i-th stage 501i may discharge the scan output node and the scan carry output node based on the scan carry signal from (i+2)-th stage, and may discharge the sensing output node and the sensing carry output node based on the sensing carry signal from (i+2)-th stage.

The i-th stage 501i may discharge the control node of the i-th stage 501i based on the carry signal from (i-2)-th stage.

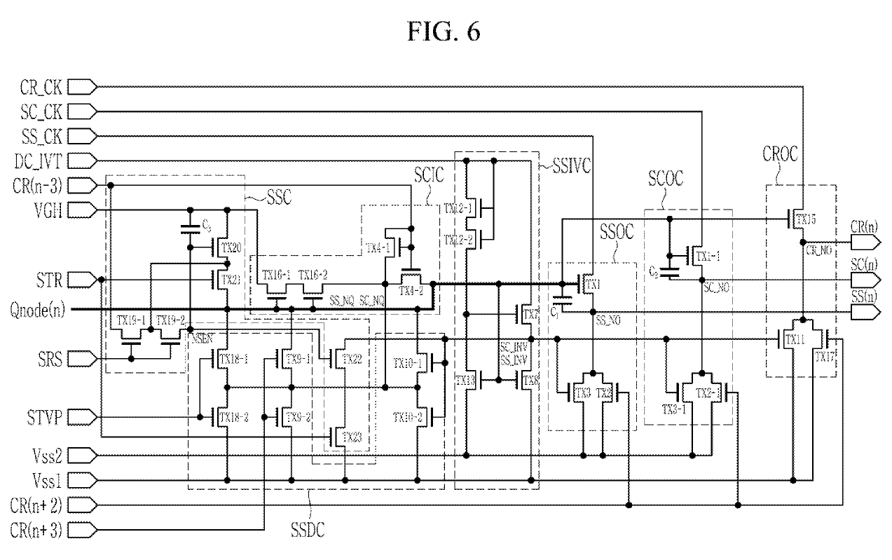

FIG. 6 shows a circuit diagram on a stage STi according to an embodiment.

As shown in FIG. 6, the stage STi may include a scan selecting circuit (SSC), a sensing input circuit (SCIC), a scan inverting circuit (SSIVC), a sensing output circuit (SCOC), a scan output circuit (SSOC), a carry output circuit (CROC), and a sensing discharge circuit (SSDC). The stage (STi) is depicted as operating based on the (n-3 carry signal (CR(n-3)), but the present disclosure should not be understood as being limited thereto, and the stage (STi) may also be operated based on arbitrary previous carry signals. To facilitate understanding and for ease of description, the enable level (or the gate-on voltage) is described as having a high level and the disable level (or the gate-off voltage) is described as having a low level, but the present disclosure should not be understood as being limited thereto, and the enable level may have a low level and the disable level may have a high level depending on the type of a transistor which is provided with the enable level or the display level. For example, if the transistor is a NMOS transistor, the enable level may have a high level and the disable level may have a low level. In contrasts, if the transistor is a PMOS transistor, the enable level may have a low level and the disable level may have a high level.

The scan selecting circuit (SSC) may change the voltage of the sensing node (NSEN) to the enable level when the sensing line selecting signal

(SRS) is applied and the input signal - i.e., the (n-3 carry signal (CR(n-3)) - has the enable level, and it may transmit the voltage of the sensing node (NSEN) to the sensing control node (SC_NQ) and the scan control node (SS_NQ) in response to the transmitting signal (STR). Therefore, when the sensing line selecting signal (SRS) is applied, the voltage of the sensing node (NSEN) of the selected stage whose input signal – i.e., the n-3 carry signal (CR(n-3)) - has the enable level has the enable level. The voltage of the sensing node (NSEN) of the remaining stages to which the sensing line selecting signal (SRS) is not applied may have a disable level.

When the blank period begins, the transmitting signal (STR) may be applied to the selected stage. Therefore, in the blank period, the sensing control node (SC_NQ) and the scan control node (SS_NQ) of the selected stage may be charged, and the sensing control node (SC_NQ) and the scan control node (SS_NQ) of the unselected stage may be discharged. Accordingly, in the blank period, the selected stage may provide a scan signal (SS) and a sensing signal (SC) to the selected gate line (GL). A real-time sensing operation may be performed for the selected gate line (GL).

The scan selecting circuit (SSC) may include nineteenth transistors (TX19-1 and TX19-2), a twentieth transistor (TX20), a twenty-first transistor (TX21), a twenty-second transistor (TX22), and a twenty-third transistor (TX23).

The nineteenth transistors (TX19-1 and TX19-2) may include a gate for receiving the sensing line selecting signal (SRS), the first terminal for receiving the n-3 scan carry signal (CR(n-3)), and the second terminal connected to the

sensing node (NSEN). The twentieth transistor (TX20) may include a third capacitor C3 including a first electrode for receiving a high gate voltage (VGH) and a second electrode connected to the sensing node (NSEN), a gate connected to the sensing node (NSEN), a first terminal for receiving a high gate voltage (VGH), and a second terminal. The twenty-first transistor (TX21) may include a gate for receiving the transmitting signal (STR), a first terminal connected to the second terminal of the twenty-first transistor (TX20), and a second terminal connected to the scan control node (SS_NQ). The twenty-third transistor (TX23) may include a gate for receiving the transmitting signal (STR), a first terminal, and a second terminal for receiving the first low gate voltage VSS1. The twenty-second transistor (TX22) may include a gate connected to the sensing node (NSEN), a first terminal connected to the scan inversion node (SS_INV), and a second terminal connected to the first terminal of the twenty-third transistor (TX23).

As shown in FIG. 6, the sensing control node (SC_NQ) and the scan control node (SS_NQ) may be the same node.

The sensing input circuit (SCIC) may charge the sensing control node (SC_NQ) based on the n-3 carry signal (CR(n-3)). For example, the sensing input circuit (SCIC) may include a fourth-1 transistor (TX4-1), a fourth-2 transistor (TX4-2), a sixteenth-1 transistor (TX16-1), and a sixteenth-2 transistor (TX16-2). The sensing input circuit (SCIC) may transmit the n-3 carry signal (CR((n-3)) having an enable level and the high gate voltage (VGH) to the sensing control node (SC_NQ) when the n-3 carry signal (CR(n-3)) has an enable level.

The fourth-1 transistor (TX4-1) may include a gate for receiving the n-3 carry signal (CR(n-3)), a first terminal for receiving the n-3 carry signal (CR(n-3)), and a second terminal. The fourth-2 transistor (TX4-2) may include a gate for receiving the n-3 carry signal (CR(n-3)), a first terminal connected to the second terminal of the fourth-1 transistor (TX4-1), and a second terminal connected to the sensing control node (SC_NQ). The sixteenth-1 transistor (TX16-1) may include a gate connected to the sensing control node (SC_NQ), a first terminal for receiving the high gate voltage (VGH), and a second terminal connected to a first terminal of the sixteenth-2 transistor (TX16-2). The sixteenth-2 transistor (TX16-2) may include a gate connected to the sensing control node (SC_NQ), a first terminal connected to the second terminal of the sixteenth-1 transistor (TX16-1), and a second terminal connected to the first terminal of the fourth-2 transistor (TX4-2).

A scan inversion circuit (SSIVC) may control the voltage of a scan inversion node (SS_INV) based on the voltage of the scan control node (SS_NQ).

The scan inversion circuit (SSIVC) may include twelfth transistors (TX12-1 and TX12-2), a seventh transistor (TX7), an eight transistor (TX8) and a thirteenth transistor (TX13.) The twelfth transistors (TX12-1 and TX12-2) may be turned on to provide a DC voltage (DC_IVT) to the scan inversion node (SS_INV) when the scan control node (SS_NQ) is discharged to the disable level. The eighth sensing transistor (TX8) may be turned on to prevent the seventh sensing transistor (TX7) from turning on when the scan control node (SS_NQ) is charged to the enable level and to provide the first low gate voltage VSS1 to the scan inversion node (SS_INV).

The twelfth-1 transistor (TX12-1) may include a gate for receiving the DC voltage (DC_IVT), a first terminal for receiving the DC voltage (DC_IVT), and a second terminal connected to a first terminal of the twelfth-2 transistor (TX12-2). The twelfth-2 transistor (TX12-2) may include a gate for receiving the DC voltage (DC_IVT), a first terminal connected to the second terminal of the twelfth-1 transistor (TX12-1), and a second terminal connected to the gate of the seventh transistor (TX7). The seventh transistor (TX7) may include a gate connected to the twelfth-2 transistor (TX12-2), a first terminal for receiving the DC voltage (DC_IVT), and a second terminal connected to the scan inversion node (SS_INV). The eighth transistor (TX8) may include a gate connected to the scan control node (SS_NQ), a first terminal connected to the scan inversion node (SS_INV), and a second terminal for receiving the first low gate voltage VSS1. The thirteenth transistor (TX13) may include a gate connected to the scan control node (SS_NQ), a first terminal connected to the gate of the seventh transistor TX7, and a second terminal for receiving the second low gate voltage VSS2.

In an embodiment, the first low gate voltage VSS1 may be lower than the second low gate voltage VSS2. For example, the first low gate voltage VSS1 may be about -9V, and the second low gate voltage VSS2 may be about -5V, but the voltages of the first low gate voltage VSS1 and the second low gate voltage VSS2 are not limited thereto. The DC voltage (DC_IVT) may be a constant voltage of about 15V, but it is not limited thereto.

As shown in FIG. 6, the scan inversion node (SS_INV) and the sensing inversion node (SC_INV) may be the same nodes.

The scan output circuit (SSOC) may control the scan output node (SS_NO) based on the voltage of the scan control node (SS_NQ) and the voltage of the scan inversion node (SS_INV) to output the scan carry signal (SSi).

The scan output circuit (SSOC) may charge the scan output node (SS_NO) to the enable level when the scan control node (SS_NQ) is charged and the scan carry clock signal (SS_CK) has the enable level, The scan output circuit (SSOC) may discharge the scan output node (SS_NO) to the second low gate voltage VSS2 when the voltage of the scan inversion node (SS_INV) has the enable level or the (n+2)th sensing carry signal (CR(n+2)) has the enable level.

The scan output circuit (SSOC) may include a first capacitor C1 and a first sensing transistor (TX1) for boosting the voltage of the scan control node (SS_NQ) and charging the scan output node (SS_NO) when the scan control node (SS_NQ) is charged and the scan carry clock signal (SS_CK) has the enable level.

The scan output circuit (SSOC) may further include a third sensing transistor (TX3) for discharging the scan output node (SS_NO) when the voltage of the scan inversion node (SS_INV) has the enable level, and a second-1 sensing transistor (TX2-1) for discharging the scan output node (SS_NO) when the (n+2)th sensing carry signal (CR(n+2)) has the enable level.

The first sensing transistor (TX1) may include a gate connected to the scan control node (SS_NQ), a first terminal for receiving the sensing clock signal (SS_CK), and a second terminal connected to the scan output node (SS_NO). The first capacitor C1 may include a first electrode connected to the scan control node (SS_NQ), and a second electrode connected to the scan output node (SS_NO). The third sensing transistor (TX3) may include a gate connected to the scan inversion node (SS_INV), a first terminal connected to the scan output node (SS_NO), and a second terminal for receiving the second low gate voltage VSS2. The second sensing transistor TX2 may include a gate for receiving the (n+2)th sensing carry signal (CR(n+2)), a first terminal connected to the scan output node (SS_NO), and a second terminal for receiving the second low gate voltage VSS2.

The sensing output circuit (SCOC) may control the sensing output node (SC_NO) based on the voltage of the sensing control node (SC_NQ) and the voltage of the sensing inversion node (SC_INV) to provide the sensing carry signal (SCi).

The sensing output circuit (SCOC) may charge the sensing output node (SC_NO) to the enable level when the sensing control node (SC_NQ) is charged and the sensing carry clock signal (SC_CK) has the enable level. The sensing output circuit (SCOC) may discharge the sensing output node (SC_NO) to the second low gate voltage VSS2 when the voltage of the sensing inversion node (SC_INV) has the enable level or the (n+2)th scan carry signal (CR(n+2)) has the enable level.

For example, the sensing output circuit (SCOC) may include a second capacitor C2 and a first-1 transistor (TX1-1), which boost the voltage of the sensing control node (SC_NQ) and charge the sensing output node (SC_NO) when the sensing control node (SC_NQ) is charged and the sensing carry clock signal (SC_CK) has the enable level.

The sensing output circuit (SCOC) may further include a third-1 transistor (TX3-1) for discharging the sensing output node (SC_NO) when the voltage of the sensing inversion node (SC_INV) has the enable level, and a second-1 transistor (TX2-1) for discharging the sensing output node (SC_NO) when the (n+2)th scan carry signal (CR(n+2)) has the enable level.

In an embodiment, the first-1 transistor (TX1-1) may include a gate connected to the sensing control node (SC_NQ), a first terminal for receiving the sensing carry clock signal (SC_CK), and a second terminal connected to the sensing output node (SC_NO). The second capacitor C2 may include a first electrode connected to the sensing control node (SC_NQ), and a second electrode connected to the sensing output node (SC_NO). The third-1 transistor (TX3-1) may include a gate connected to the sensing inversion node (SC_INV), a first terminal connected to the sensing output node (SC_NO), and a second terminal for receiving the second low gate voltage VSS2. The second-1 transistor (TX2-1) may include a gate for receiving the (n+2)th scan carry signal (CR(n+2)), a first terminal connected to the sensing output node (SC_NO), and a second terminal for receiving the second low gate voltage VSS2.

The carry output circuit (CROC) may control the scan carry output node (CR_NO) based on the voltage of the sensing control node (SC_NQ) and the voltage of the sensing inversion node (SC_INV) to output the carry signal (CRi).

The carry output circuit (CROC) may charge the scan carry output node (CR_NO) to the enable level when the sensing control node (SC_NQ) is charged and the carry clock signal (CR_CK) has the enable level. The carry ouput circuit (CROC) may discharge the scan carry output node (CR_NO) to the first low gate voltage VSS1 when the voltage of the sensing inversion node (SC_INV) has the enable level or the (n+2)th scan carry signal (CR(n+2)) has the enable level.

Therefore, the carry clock signal (CR_CK) may be output as the carry signal (CRi) while the scan carry output node (CR_NO) is charged.

For example, the carry output circuit (CROC) may include a fifteenth transistor (TX15) for charging the scan carry output node (CR_NO) when the sensing control node (SC_NQ) is charged and boosted and the first carry clock signal (CR_CK) has the enable level, an eleventh transistor (TX11) for discharging the scan carry output node (CR_NO) when the voltage of the sensing inversion node (SC_INV) has the enable level, and a seventeenth transistor (TX17) for discharging the scan carry output node (CR_NO) when the (n+2)th carry signal (CR(n+2)) has the enable level.

In an embodiment, the fifteenth transistor (TX15) may include a gate connected to the sensing control node (SC_NQ), a first terminal for receiving the carry clock signal (CR_CK), and a second terminal connected to the scan carry output node (CR_NO). The eleventh transistor (TX11) may include a gate connected to the sensing inversion node (SC_INV), a first terminal connected to the scan carry output node (CR_NO), and a second terminal for receiving the first low gate voltage VSS1. The seventeenth transistor (TX17) may include a gate for receiving the (n+2)th scan carry signal (CR(n+2)), a first terminal connected to the scan carry output node (CR_NO), and a second terminal for receiving the first low gate voltage VSS1.

The sensing discharge circuit (SSDC) may discharge the scan control node (SS_NQ) and the sensing control node (SS_NQ). The sensing discharge circuit (SSDC) may discharge the scan control node (SS_NQ) based on the voltage of the scan start signal (STVP), the (n+3)th sensing carry signal (CR(n+3)), or the scan inversion node (SS_INV).

For example, the sensing discharge circuit (SSDC) may include an eighteenth-1 transistor (TX18-1) and an eighteenth-2 transistor (TX18-2) for discharging the sensing control node (SC_NQ) when the scan start signal (STVP) has the enable level, a ninth-1 transistor (TX9-1) and a ninth-2 transistor (TX9-2) for discharging the sensing control node (SC_NQ) when the (n+3)th scan carry signal (CR(n+3)) has the enable level, and a tenth-1 transistor (TX10-1) and a tenth-2 transistor (TX10-2) for discharging the sensing control node (SC_NQ) when the voltage of the sensing inversion node (SC_INV) has the enable level.

In an embodiment, the eighteenth-1 transistor (TX18-1) may include a gate for receiving a scan start signal (STVP), a first terminal connected to a sensing control node (SC_NQ), and a second terminal connected to a first terminal of the eighteenth-2 transistor (TX18-2), and the eighteenth-2 transistor (TX18-2) may include a gate for receiving a scan start signal (STVP), a first terminal connected to the eighteenth-1 transistor (TX18-1), and a second terminal for receiving the first low gate voltage VSS1.

The ninth-1 transistor (TX9-1) may include a gate for receiving the (n+3)th scan carry signal (CR(n+3)), a first terminal connected to the sensing control node (SC_NQ), and a second terminal connected to a first terminal of the ninth-2 transistor (TX9-2), and the ninth-2 transistor (TX9-2) may include a gate for receiving the (n+3)th scan carry signal (CR(n+3)), a first terminal connected to the second terminal of the ninth-1 transistor (TX9-1), and a second terminal for receiving the first low gate voltage VSS1. The tenth-1 transistor (TX10-1) may include a gate connected to the sensing inversion node (SC_INV), a first terminal connected to sensing control node (SC_NQ), and a second terminal connected to a first terminal of the tenth-2 transistor (TX10-2) may include a gate connected to the sensing inversion node (SC_INV), a first terminal connected to the second terminal of the tenth-1 transistor (TX10-1), and a second terminal for receiving the first low gate voltage VSS1.

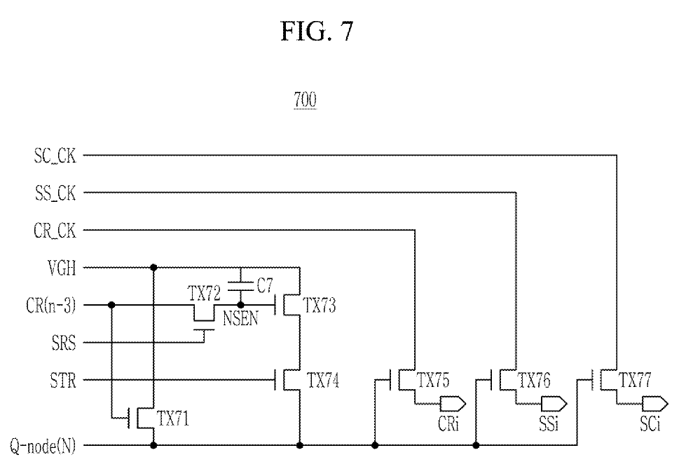

FIG. 7 shows a circuit diagram illustrating a portion of the stage according to an embodiment.

As shown in FIG. 7, the stage 700 is a schematic circuit diagram illustrating a portion of the stage STi in FIG. 6.

For example, the stage 700 may include a first transistor (TX71), a second transistor (TX72), a third transistor (TX73), a fourth transistor (TX74), a fifth transistor (TX75), a sixth transistor (TX76), a seventh transistor (TX77), and a capacitor C7. For example, the first transistor (TX71), the second transistor (TX72), the third transistor (TX73), the fourth transistor (TX74), the fifth transistor (TX75), the sixth transistor (TX76), the seventh transistor (TX77), and the capacitor C7 may correspond to the fourth-2 transistor (TX4-2), the nineteen-1 and nineteen-2 transistors (TX19-1 and TX19-2), the twentieth transistor (TX20), the twenty-first transistor (TX21), the fifteenth transistor (TX15), the first transistor (TX1), the first-1 transistor (TX1-1), and the third capacitor C3 shown in FIG. 6, respectively.

The second transistor (TX72) may change the voltage of the sensing node (NSEN) to the enable level when the corresponding sensing line selecting signal (SRS) and the n-3 carry signal (CR(n-3)) having the enable level are applied. Accordingly, the third transistor (TX73) may be turned on. The fourth transistor (TX74) may transmit the voltage of the sensing node (NSEN) to the Q node (which is the same node as the sensing control node (SC_NQ) and the scan control node (SS_NQ)) in response to the transmitting signal (STR). Therefore, when the sensing line selecting signal (SRS) is applied, the voltage of the sensing node (NSEN) of the selected stage which receives the sensing line selecting signal (SRS) and the n-3 carry signal (CR(n-3)) having the enable signal may have the enable level. The voltage of the sensing node (NSEN) of the remaining unselected stages which do not receive the sensing line selecting signal (SRS) may have the disable level.

When the blank period begins, the transmitting signal (STR) may be applied to the selected stage. In the blank period, the Q node of the selected stage may be charged, and the Q node of the unselected stage may be discharged.

The fifth transistor (TX75) may output the carry signal (CRi) having the enable level when the Q node is charged and the carry clock signal (CR_CK) has the enable level.

The sixth transistor (TX76) may output the scan carry signal (SSi) having the enable level when the Q node is charged and the scan carry clock signal (SS_CK) has the enable level.

The seventh transistor (TX77) may output the sensing carry signal (SCi) having the enable level when the Q node is charged and the sensing carry clock signal (SC_CK) has the enable level.

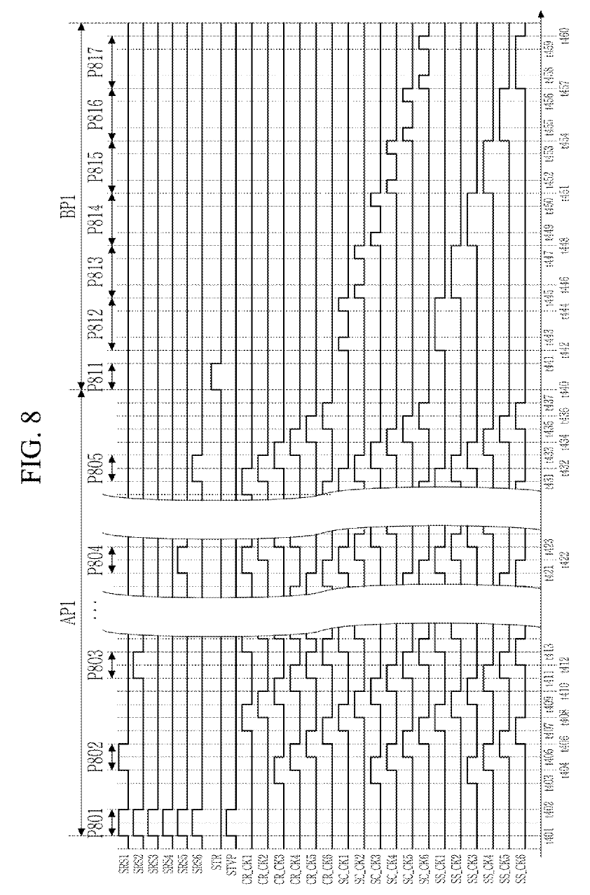

FIG. 8 shows a timing diagram illustrating an operation of a gate driver according to an embodiment.

To facilitate understanding and for ease of description, it is assumed that the gate driver 35 in FIG. 8 includes six stages, and accordingly, the display panel 20 may be divided into six regions R1 to R6.

The gate driver 35 may drive the gate lines (GL) during one frame period including the active period AP1 and the blank period BP1.

At t401, the sensing line selecting signals (SRS1 to SRS6) and the scan start signal (STVP) may transition to the enable level. Each of the sensing line selecting signals (SRS1 to SRS6) may correspond to each of the stages (501a, 501b, …, 501i, …, 501m). Here, the scan start signal (STVP) may define a start of the operation of the clock signal generator 351 in FIG. 4. Each of the clock signals in the carry clock signal (CR_CK), the sensing carry clock signal (SC_CK) or the scan carry clock signal (SS_CK) may have different phases.

The sensing line selecting signals (SRS1 to SRS6) may select a corresponding stage from among the stages (501a, 501b, …, 501i, …, 501m), and each stage may output the corresponding scan carry signal (SS) and the sensing carry signal (SC). Therefore, the gate driver 35 may output the scan carry signal (SS) and the sensing carry signal (SC) by independently controlling the stages (501a, 501b, …, 501i, …, 501m) through the sensing line selecting signals (SRS1 to SRS6).

At t402, the sensing line selecting signals (SRS1 to SRS6) and the scan start signal (STVP) may transition to the disable level.

In the first period P801, the pulse of the scan start signal (STVP) is generated so that the clock signal generator 351 may generate each clock signals (CR_CK, SC_CK, and SS_CK).

At t403, the third carry clock signal (CR_CK3), the third sensing carry clock signal (SC_CK3), and the third scan carry clock signal (SS_CK3) may transition from the disable level to the enable level.

At t404, the first sensing line selecting signal SRS1 may transition from the disable level to the enable level. The fourth carry clock signal (CR_CK4), the fourth sensing carry clock signal (SC_CK4), and the fourth scan carry clock signal (SS_CK4) may transition from the disable level to the enable level.

At t405, the fifth carry clock signal (CR_CK5), the fifth sensing carry clock signal (SC_CK5), and the fifth scan carry clock signal (SS_CK5) may transition from the disable level to the enable level, and the third carry clock signal (CR_CK3), the third sensing carry clock signal (SC_CK3), and the third scan carry clock signal (SS_CK3) may transition from the enable level to the disable level.

At t406, the first sensing line selecting signal SRS1 may transition from the enable level to the disable level. The fourth carry clock signal (CR_CK4), the fourth sensing carry clock signal (SC_CK4), and the fourth scan carry clock signal (SS_CK4) may transition from the enable level to the disable level, and the sixth carry clock signal (CR_CK6), the sixth sensing carry clock signal (SC_CK6), and the sixth scan carry clock signal (SS_CK6) may transition from the disable level to the enable level.

In the second period P802, while the first sensing line selecting signal SRS1 maintains the enable level, the third carry clock signal (CR_CK3), the fourth carry clock signal (CR_CK4), and the fifth carry clock signal (CR_CK5) may sequentially have the enable level.

Referring to FIG. 7 together, charges corresponding to the level of VGH may be stored in the capacitor C7 in response to the first sensing line selecting signal SRS1 having the enable level and the n-3 carry signal (CR(n-3)) having the enable level. When the first sensing line selecting signal SRS1 transitions to the disable level, one end of the second transistor TX72 may float. A voltage stored in the capacitor C7 may be applied to the gate of the third transistor TX73. The Q node may be charged by the carry clock signal (CR_CK) having the enable level. Accordingly, the gate driver 35 may generate sensing clock signals (SC_CK3, SC_CK4, and SC_CK5) having the enable level and scan clock signals (SC_CK3, SC_CK4, and SC_CK5) having the enable level based on the carry clock signal (CR_CK3, CR_CK4, and CR_CK5). Other sensing clock signals (SC_CK6, SC_CK1, and SC_CK2) and other scan clock signals (SC_CK6, SC_CK1, and SC_CK2) maintain the disable level in the second period P802.

At t407, the fifth carry clock signal (CR_CK5), the fifth sensing carry clock signal (SC_CK5), and the fifth scan carry clock signal (SS_CK5) may transition from the enable level to the disable level, and the first carry clock signal (CR_CK1), the first sensing carry clock signal (SC_CK1), and the first scan carry clock signal (SS_CK1) may transition from the disable level to the enable level.

At t408, the second carry clock signal (CR_CK2), the second sensing carry clock signal (SC_CK2), and the second scan carry clock signal (SS_CK2) may transition from the disable level to the enable level, and the sixth carry clock signal (CR_CK6), the sixth sensing carry clock signal (SC_CK6), and the sixth scan carry clock signal (SS_CK6) may transition from the enable level to the disable level.

At t409, the first carry clock signal (CR_CK1), the first sensing carry clock signal (SC_CK1), and the first scan carry clock signal (SS_CK1) may transition from the enable level to the disable level.

Unless otherwise stated, the description of the carry clock signals (CR_CK1, CR_CK2, …, CR_CK6), the sensing carry clock signals (SC_CK1, SC_CK2, …, SC_CK6), and the scan carry clock signals (SS_CK1, SS_CK2, …, SS_CK6) in t403 to t408 may also be applicable to t409 to t413, t421 to t423, and t431 to t437. That is, the carry clock signals (CR_CK1, CR_CK2, …, CR_CK6), the sensing carry clock signals (SC_CK1, SC_CK2, …, SC_CK6), and the scan carry clock signals (SC_CK1, SC_CK2, …, SC_CK6) may toggle with a predetermined period.

At t411, the second sensing line selecting signal SRS2 may transition from the disable level to the enable level. At t413, the second sensing line selecting signal SRS2 may transition from the enable level to the disable level.

In t421, the fifth sensing line selecting signal SRS5 may transition from the disable level to the enable level. At t423, the fifth sensing line selecting signal SRS5 may transition from the enable level to the disable level.

In the third period P803, while the second sensing line selecting signal SRS2 maintains the enable level, the third carry clock signal (CR_CK3), the fourth carry clock signal (CR_CK4), and the fifth carry clock signal (CR_CK5) may sequentially have the enable level.

Similar to the second period P802, in the third period P803, the gate driver 35 may generate sensing clock signals (SS_CK3, …, SS_CK6) and scan clock signals (SS_CK3, …, SS_CK6) based on the carry clock signals (CR_CK3, CR_CK4, and CR_CK5).

In the fourth period P804, while the fifth sensing line selecting signal SRS5 maintains the enable level, the sixth carry clock signal (CR_CK6), the first carry clock signal (CR_CK1), and the second carry clock signal (CR_CK2) may sequentially have the enable level.

Similar to the second period P802, in the fourth period P804, the gate driver 35 may generate sensing clock signals (SC_CK6, SC_CK1, and SC_CK2) having the enable level and scan clock signals (SC_CK6, SC_CK1, and SC_CK2) having the enable level based on the carry clock signals (CR_CK6, CR_CK1, and CR_CK2). Other sensing clock signals (SC_CK3, SC_CK4, and SC_CK5) and other scan clock signals (SS_CK3, SS_CK4, and SS_CK5) maintain the disable level in the fourth period P804.

At t431, the sixth sensing line selecting signal SRS6 may transition from the disable level to the enable level. At t433, the sixth sensing line selecting signal SRS6 may transition from the enable level to the disable level.

In the fifth period P805, while the sixth sensing line selecting signal SRS6 maintains the enable level, the first carry clock signal (CR_CK1), the second carry clock signal (CR_CK2), and the third carry clock signal (CR_CK3) may sequentially have the enable level.

Similar to the second period P802, the fifth period P805 gate driver 35 may generate sensing clock signals (SC_CK1, SC_CK2, and SC_CK3) having the enable level and scan clock signals (SS_CK1, SS_CK2, and SS_CK3) having the enable level based on the carry clock signals (CR_CK1, CR_CK2, and CR_CK3). Other sensing clock signals (SC_CK4, SC_CK5, and SC_CK6) and other scan clock signals (SS_CK4, SS_CK5, and SS_CK6) maintain the disable level in the fifth period P805.

At t440, the transmitting signal (STR) may transition from the disable level to the enable level. At t441, the transmitting signal (STR) may transition from the enable level to the disable level.

The blank period BP1 may include a sixth period P811, a seventh period P812, an eighth period P813, a ninth period P814, a tenth period P815, an eleventh period P816, and a twelfth period P817.

In the sixth period P811, the fourth transistor TX74 is turned on in response to the transmitting signal (STR) having the enable level, and VGH is transmitted to the Q node so that the Q node may be charged.

At t442, the first sensing carry clock signal (SC_CK1) and the first scan carry clock signal (SS_CK1) may transition from the disable level to the enable level.

At t443, the first sensing carry clock signal (SC_CK1) may transition from the enable level to the disable level. At t444, the first sensing carry clock signal (SC_CK1) may transition from the disable level to the enable level.

At t445, the first sensing carry clock signal (SC_CK1) and the first scan carry clock signal (SS_CK1) may transition from the enable level to the disable level. The second sensing carry clock signal (SC_CK2) and the second scan carry clock signal (SS_CK2) may transition from the disable level to the enable level.

In the seventh period P812, the gate driver 35 may output a scan carry signal SS1 in response to the charged Q node and the first scan carry clock signal (SS_CK1) having the enable level. The gate driver 35 may output a sensing carry signal SC1 by in response to charged Q node and the first sensing carry clock signal (SS_CK1) having the enable level.

At t447, the second sensing carry clock signal (SC_CK2) may transition from the enable level to the disable level. At t447, the second sensing carry clock signal (SC_CK2) may transition from the disable level to the enable level.

At t448, the second sensing carry clock signal (SC_CK2) and the second scan carry clock signal (SS_CK2) may transition from the enable level to the disable level. The third sensing carry clock signal (SC_CK3) and the third scan carry clock signal (SS_CK3) may transition from the disable level to the enable level.

In the eighth period P813, the gate driver 35 may output the scan carry signal SS2 in response to the charged Q node and the second scan carry clock signal (SS_CK2) having the enable level. The gate driver 35 may output the sensing carry signal SC2 in response to the charged Q node and the second sensing carry clock signal (SS_CK2) having the enable level.

At t449, the third sensing carry clock signal (SC_CK3) may transition from the enable level to the disable level. At t450, the third sensing carry clock signal (SC_CK3) may transition from the disable level to the enable level.

At t451, the third sensing carry clock signal (SC_CK3) and the third scan carry clock signal (SS_CK3) may transition from the enable level to the disable level. The fourth sensing carry clock signal (SC_CK4) and the fourth scan carry clock signal (SS_CK4) may transition from the disable level to the enable level.

In the ninth period P814, the gate driver 35 may output the scan carry signal SS3 in response to the charged Q node and the third scan carry clock signal (SS_CK3) having the enable level. The gate driver 35 may output the sensing carry signal SC3 in response to the charged Q node and the third sensing carry clock signal (SS_CK3) having the enable level.

At t452, the fourth sensing carry clock signal (SC_CK4) may transition from the enable level to the disable level. At t453, the fourth sensing carry clock signal (SC_CK4) may transition from the disable level to the enable level.

At t454, the fourth sensing carry clock signal (SC_CK4) and the fourth scan carry clock signal (SS_CK4) may transition from the enable level to the disable level. The fifth sensing carry clock signal (SC_CK5) and the fifth scan carry clock signal (SS_CK5) may transition from the disable level to the enable level.

In the tenth period P815, the gate driver 35 may output the scan carry signal SS4 in response to the charged Q node and the fourth scan carry clock signal (SS_CK4) having the enable level. The gate driver 35 may output the sensing carry signal SC4 in response to the charged Q node and the fourth sensing carry clock signal (SS_CK4) having the enable level.

At t455, the fifth sensing carry clock signal (SC_CK5) may transition from the enable level to the disable level. At t456, the fifth sensing carry clock signal (SC_CK5) may transition from the disable level to the enable level.

At t457, the fifth sensing carry clock signal (SC_CK5) and the fifth scan carry clock signal (SS_CK5) may transition from the enable level to the disable level. The sixth sensing carry clock signal (SC_CK6) and the sixth scan carry clock signal (SS_CK6) may transition from the disable level to the enable level.

In the eleventh period P816, the gate driver 35 may output the scan carry signal SS5 in response to the charged Q node and the fifth scan carry clock signal (SS_CK5) having the enable level. The gate driver 35 may output the sensing carry signal SC5 in response to the charged Q node and the fifth sensing carry clock signal (SS_CK5) having the enable level.

At t458, the sixth sensing carry clock signal (SC_CK6) may transition from the enable level to the disable level. At t459, the sixth sensing carry clock signal (SC_CK6) may transition from the disable level to the enable level.

At t460, the sixth sensing carry clock signal (SC_CK6) and the sixth scan carry clock signal (SS_CK6) may transition from the enable level to the disable level.

In the twelfth period P817, the gate driver 35 may output the scan carry signal SS6 in response to the charged Q node and the sixth scan carry clock signal (SS_CK6) having the enable level. The gate driver 35 may output the sensing carry signal SC6 in response to the charged Q node and the sixth sensing carry clock signal (SS_CK6) having the enable level.

The gate driver 35 may sequentially output the scan carry signal (SS) and the sensing carry signal (SC) during the blank period BP1. The gate driver 35 may generate the scan carry signal (SS) and the sensing carry signal (SC) corresponding to each of the six stages in the blank period BP1. This allows sensing data corresponding to each of the regions (for example, from the first region R1 to the sixth region R6) to be generated during the blank period BP1 within one frame, thereby reducing the sensing period to 1/6.

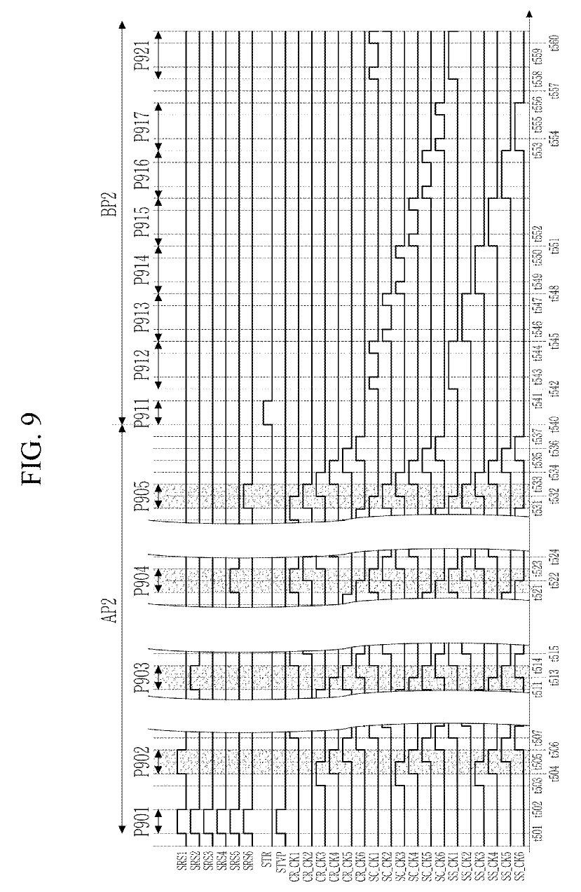

FIG. 9 shows a timing diagram illustrating an operation of a gate driver according to an embodiment.

Unless otherwise stated, the description for the active period AP1 in FIG. 8 may equally apply to the active period AP2.

The blank period BP2 may include a sixth period P911, a seventh period P912, an eighth period P913, a ninth period P914, a tenth period P915, an eleventh period P916, a twelfth period P917, and a thirteenth period P921.

Unless otherwise stated, the description of the sixth period P811, the seventh period P812, the eighth period P813, the ninth period P814, the tenth period P815, the eleventh period P816, and the twelfth period P817 of FIG. 8 may equally be applied to the sixth period P911, the seventh period P912, the eighth period P913, the ninth period P914, the tenth period P915, the eleventh period P916, and the twelfth period P917, respectively.

The description of the sixth period P811 may also be applied to the thirteenth period P921.

The gate driver 35 may sequentially output the scan carry signal (SS) and the sensing carry signal (SC) during the blank period BP2. The gate driver 35 may output the scan carry signal (SS) and the sensing carry signal (SC) multiple times during the blank period BP2. For example, as shown in FIG. 9, the gate driver 35 may generate the sensing carry signal SS1 twice based on the sensing carry clock signal (SC_CK1). This allows the sensing data corresponding to each of the regions (for example, from the first region R1 to the sixth region R6) to be generated multiple times during the blank period BP2 within one frame, thereby shortening the sensing period to less than 1/6, and controlling the interval between the sensing lines.

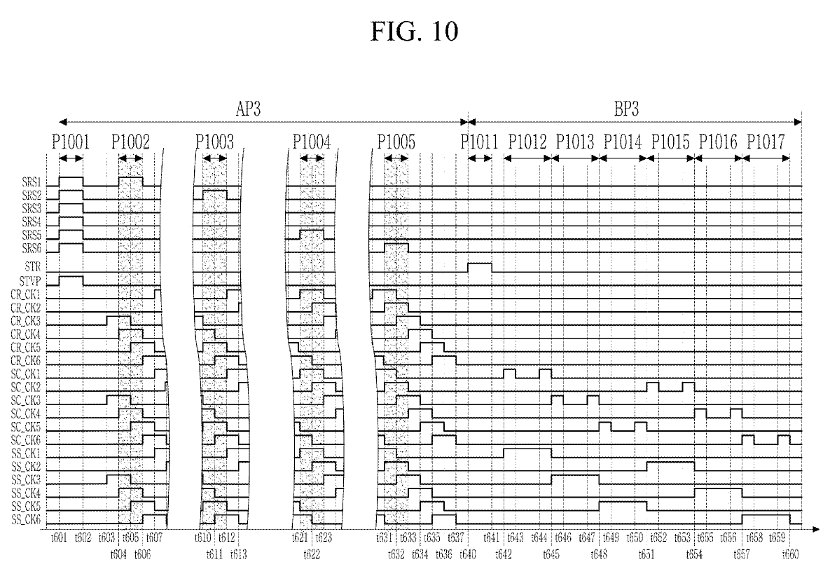

FIG. 10 shows a timing diagram illustrating an operation of a gate driver according to an embodiment.

Unless otherwise stated, the description for the active period AP1 in FIG. 8 may equally apply to the active period AP3.

The blank period BP3 may include a sixth period P1011, a seventh period P1012, an eighth period P1013, a ninth period P1014, a tenth period P1015, an eleventh period P1016, and a twelfth period P1017.

Unless otherwise stated, the description of the sixth period P811, the seventh period P812, the ninth period P814, the eleventh period P816, the eighth period P813, the tenth period P815, and the twelfth period P817 of FIG. 8 may equally be applied to the sixth period P1011, the seventh period P1012, the eighth period P1013, the ninth period P1014, the tenth period P1015, the eleventh period P1016, and the twelfth period P1017, respectively.

As shown in FIG. 10, the gate driver 35 may output the scan carry signal (SS) and the sensing carry signal (SC), by changing the order of the scan carry signal (SS) and the sensing carry signal (SC) as explained above with reference to FIG. 8, during the blank period BP3. That is, the gate driver 35 may adjust the period for generating sensing data. For example, referring to FIG. 5, the gate driver 35 may sequentially generate the scan carry signal SS1 and the sensing carry signal SC1 corresponding to the stage 501a, the scan carry signal SS2 and the sensing carry signal SC2 corresponding to the stage 501b, etc., but the present disclosure is not limited thereto. For example, the gate driver 35 may not sequentially generate the sensing carry signal and the scan carry signal output to the sensing line corresponding to each of the plurality of stages, but may generate the sensing carry signal and the scan carry signal on every other line (e.g., on odd lines or even lines) corresponding to each of the plurality of stages. To do this, the gate driver 35 may adjust the period for generating the sensing carry clock signal (SC_CK1, SC_CK3, and SC_CK5), and the scan carry clock signal (SS_CK1, SS_CK3, and SS_CK5) first. Afterwards, the gate driver 35 may generate the sensing carry clock signal (SC_CK2, SC_CK4, and SC_CK6) and the scan carry clock signal (SS_CK2, SS_CK4, and SS_CK6).

The gate driver 35 may sequentially output the scan carry signal (SS) and the sensing carry signal (SC) during the blank period BP3. The gate driver 35 may generate the scan carry signal (SS) and the sensing carry signal (SC) corresponding to each of the six stages in the blank period BP3. This allows the sensing data corresponding to each of the regions (for example, from the first region R1 to the sixth region R6) to be generated during the blank period BP3 within one frame, thereby reducing the sensing period to 1/6. The space between the sensing lines may be adjusted.

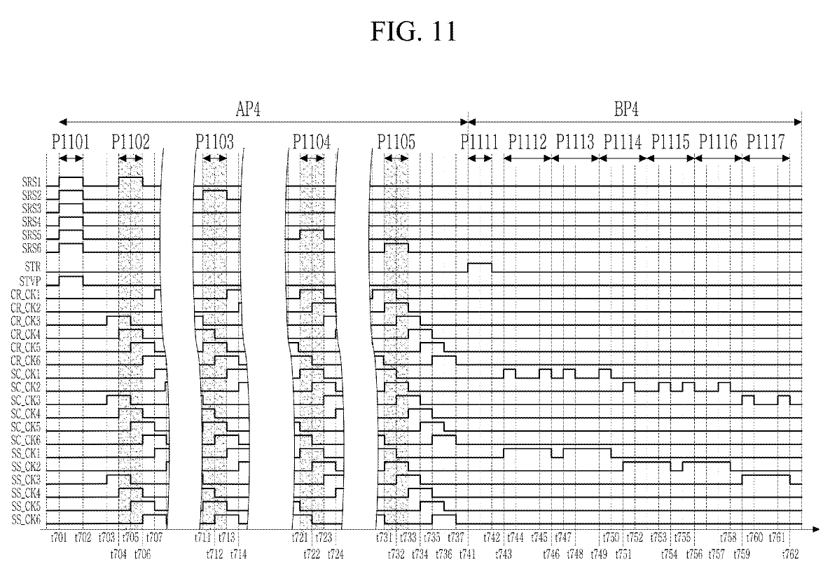

FIG. 11 shows a timing diagram illustrating an operation of a gate driver according to an embodiment.

Unless otherwise stated, the description for the active period AP1 in FIG. 8 may equally apply to the active period AP4.

The blank period BP4 may include a sixth period P1111, a seventh period P1112, an eighth period P1113, a ninth period P1114, a tenth period P1115, and an eleventh period P1116.

Unless otherwise stated, the description of the sixth period P811 in FIG. 8 may equally apply to the sixth period P1111, the description of the seventh period P812 may equally apply to the seventh period P1112 and the eighth period P1113, respectively, the description of the eighth period P813 may equally apply to each of the ninth period P1114 and the tenth period P1115, and the description of the ninth period P814 may be applied to the eleventh period P1116.

The gate driver 35 may sequentially output the scan carry signal (SS) and the sensing carry signal (SC) during the blank period BP4. The gate driver 35 may output the scan carry signal (SS) and the sensing carry signal (SC) multiple times during the blank period BP4. For example, as shown in FIG. 11, the gate driver 35 may generate the scan carry signal (SS) and the sensing carry signal (SC) multiple times based on the corresponding sensing carry clock signal (SC_CK) and the scan carry clock signal (SS_CK). This allows the sensing data corresponding to each of the regions (for example, from the first region R1 to the sixth region R6) to be generated multiple times during the blank period BP2 within one frame, thereby reducing the sensing period to less than 1/6.

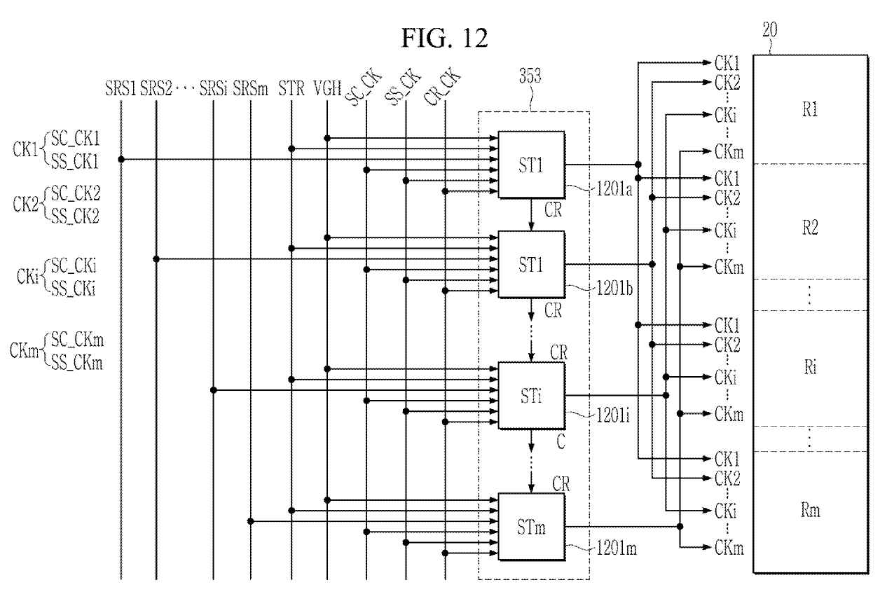

FIG. 12 shows a portion of a display device according to an embodiment.

As shown in FIG. 12, the gate signal generator 353 may include stages (1201a, 1201b, …, 1201i, …, 1201m). Each of the stages (1201a, 1201b, …, 1201i, …, 1201m) may include a scan carry signal generator, a sensing carry signal generator, and a carry signal generator.

Each of the stages (1201a, 1201b, …, 1201i, …, 1201m) may generate the scan carry signal (SSi) and the sensing carry signal (SCi), and output the generated scan carry signal (SSi) and sensing carry signal (SCi) to a plurality of regions (R1, R2, …, Ri, …, Rm) through a line (CK1, CK2, …, CKi, …., or CKm). Each of the line (CK1, CK2, …, CKi, …, CKm) is connected to a corresponding stage among the plurality of stages (1201a, 1201b, …, 1201i, …, 1201m) and transfer the scan carry signal (SSi) and the sensing carry signal (SCi) to a plurality of regions (R1, R2, …, Ri, …, Rm).

Although not shown in FIG. 12, the sensing line selecting signal generator 355 in FIG. 4 may select a target stage to be activated among the stages, and may control the sensing line selecting signals (SRS1, SRS2, …, SRSi, …, SRSm) corresponding to the target stage to have the enable level.

Each of the stages (1201a, 1201b, …, 1201i, …, 1201m) may receive a corresponding sensing line selecting signal from the sensing line selecting signal generator 355. For example, the i-th stage 1201i may receive the i-th sensing line selecting signal (SRSi) from the sensing line selecting signal generator 355. Each of the stages (1201a, 1201b, …, 1201i, …, 1201m) may receive the scan carry clock signal (SS_CK), the sensing carry clock signal (SC_CK), and the carry clock signal (CR_CK) from the clock signal generator 351. Each of the stages (1201a, 1201b, …, 1201i, …, 1201m) may receive the transmitting signal (STR) and the high gate voltage (VGH).

For example, when the i-th stage 1201i is the target stage, the sensing line selecting signal generator 355 may generate the i-th sensing line selecting signal (SRSi) corresponding to the i-th stage 1201i. The i-th stage 1201i may generate the corresponding scan carry signal (SSi) and the sensing carry signal (SCi) based on the sensing line selecting signal (SRSi) having the enable level. For example, the i-th stage 1201i may generate the scan carry signal (SSi) and the sensing carry signal (SCi) based on the sensing line selecting signal (SRSi), the transmitting signal (STR), the high gate voltage (VGH), and the previous carry signal (CRi-1). The scan carry signal (SSi) and the sensing carry signal (SCi) generated from the i-th stage STi may be transmitted to each of the regions (R1, R2, …, Ri, …, Rm) through a line CKi connected to the i-th stage STi.

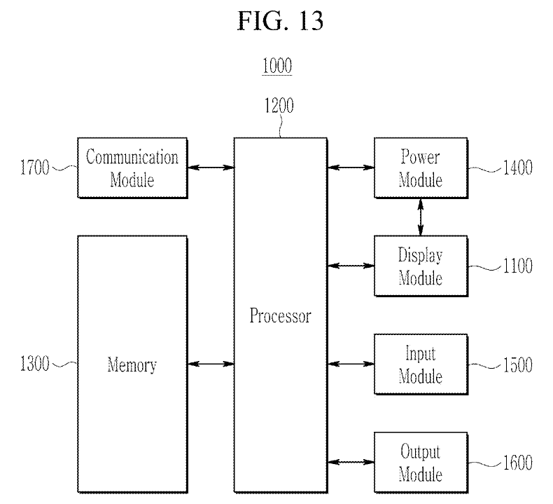

FIG. 13 shows a block diagram on an electronic device according to an embodiment.

Referring to FIG. 13, the electronic device 1000 according to an embodiment may include a display module 1100, a processor 1200, a memory 1300, and a power module 1400.

The processor 1200 may include at least one of a central processing unit (CPU), an application processor (AP), a graphic processing unit (GPU), a communication processor (CP), an image signal processor (ISP), and a controller. In an embodiment, the processor 1200 may control input/output of data stored in the memory 1300.

The memory 1300 may store data information necessary for the operation of the processor 1200 or the display module 1100. In an embodiment, the memory 1300 may store image data for displaying image through the display module 1100. When the processor 1200 executes an application stored in the memory 1300, an image data signal and/or an input control signal may be transmitted to the display module 1100, and the display module 1100 may process the received signals including the image data signal and/or the input control signal and may display the image through a display screen of the display module 1100. For example, the display module 1100 may receive the image data from the memory 1300 and may output the received image data.

The display module 1100 may be the display device 10 described with reference to FIGS. 1 to FIG. 12.

The power module 1400 may include a power supply module, such as a power adaptor or a battery device, and a power conversion module for converting the power supplied from the power supply module and generating power required for the operation of the electronic device 1000.

The electronic device 1000 may further include an input module 1500, an output module 1600 and/or a communication module 1700.

The input module 1500 may provide input information to the processor 1200 and/or the display module 1100. The input module 1500 may include various sensor modules as well as physical buttons, a keyboard, and a microphone. Examples of the sensor modules may include touch sensors, pressure sensors, distance sensors, position sensors, digitizers, motion detection sensors, camera sensors, photodetectors, photoelectric conversion sensors, temperature sensors, and biometric sensors such as blood pressure sensors, blood sugar sensors, electrocardiogram sensors, and heart rate sensors.

The output module 1600 may receive information other than the image received from the processor 1200 and may provide it to the user. Examples of the output modules 1600 may include an acoustic module, a haptic module, a light emitting module, etc., and may include other electronic device-specific functional modules (e.g., a cooling module of a refrigerator, etc.).

The communication module 1700 is a module for transmitting/receiving information between the electronic device 1000 and external devices, and may include a receiver and a transmitter. The communication module 1700 may include various wireless communication modules such as a mobile communication module, a Wi-Fi module, a Bluetooth module, or various wired communication modules.

At least one of the components of the electronic device 1000 described above may be included in the display device according to the embodiments described above. Some of the individual modules functionally included in a module may be included in the display device, while others may be provided separately from the display device. For example, the display device may include the display module 1100, and the processor 1200, the memory 1300, and the power module 1400 may be provided in the form of devices in the electronic device 1000 other than the display device.

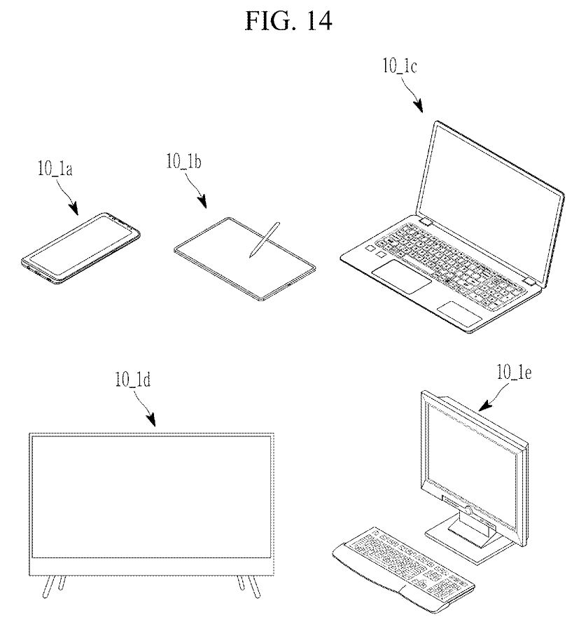

FIGS. 14 to FIG.16 show schematic diagrams on an electronic device according to various embodiments. FIGS. 14 to FIG. 16 show examples of various electronic devices in which a display device according to embodiments is applied.

FIG. 14 shows examples of electronic devices, including a smartphone (10_1a), a tablet PC (10_1b), a laptop (10_1c), a TV (10_1d), and a desk monitor (10_1e).

The smartphone (10_1a) may include input modules such as a touch sensor and a communication module in addition to the display module 1100. The smartphone (10_1a) may process information received through the communication module or other input modules and may display the information through the display module of the display device.

Similar to the smartphone (10_1a), the tablet PC (10_1b), the laptop (10_1c), the TV (10_1d), and the desk monitor (10_1e) may include a display module and an input module, and in some cases, may further include a communication module.

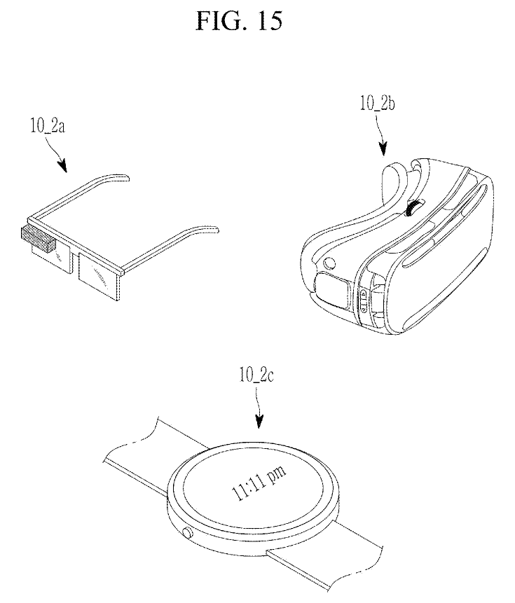

FIG. 15 shows an example where an electronic device including a display module is applied to a wearable electronic device. The wearable electronic device may be smart glasses (10_2a), a head mounted display (10_2b), a smartwatch (10_2c), etc.

The smart glasses (10_2a) and the head mounted displays (10_2b) may include a display module for emitting a display image and a reflector for reflecting the emitted display image and providing it to the user’s eyes, thereby providing a virtual reality or augmented reality screen to the user.

The smartwatch (10_2c) may include a biometric sensor as an input device and may provide biometric information recognized by the biometric sensor to the user through the display module.

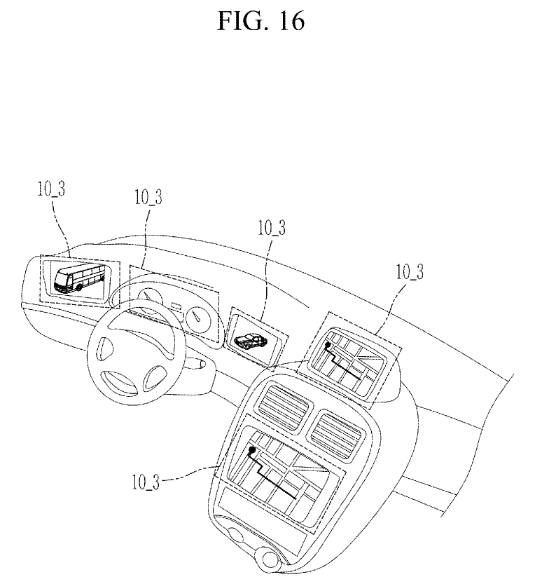

FIG. 16 shows an example where an electronic device including a display module is applied to a vehicle. For example, the electronic device 10_3 may be applied to a vehicle's instrument panel, center fascia, etc., or a center information display (CID) placed on the vehicle's dashboard, or a room mirror display replacing a side mirror.

Although not illustrated, the electronic devices to which the display devices according to embodiments are applied may include not only devices that mainly display screens, such as billboards, electronic boards, and game consoles, but also various home appliances that display information through display modules, such as refrigerators, washing machines, dryers, air conditioners, and robot vacuum cleaners. When the display module has a light transmitting function, it may be applied to electronic devices such as a smart window or a transparent display device that displays backgrounds and display images together. The types of electronic devices according to the embodiment are not limited by the examples, and various other electronic devices not illustrated may also be applied.

The display device according to an embodiment may be applied to various electronic devices. The electronic device according to an embodiment includes the display device described above, and may further include a module or device having additional functions other than the display device.

Although an embodiment has been described in detail above, the scope of the present disclosure is not limited thereto, and various modifications and improvements made by a person of an ordinary skill in the art using the technical feature of the present disclosure defined in the following claims also fall within the scope of the present disclosure.

What is claimed is:

1. A display device comprising:
a display panel divided into a plurality of regions, each of the plurality of regions including at least one gate line and a plurality of pixels connected to the at least one gate line;
a timing controller configured to receive a mode selecting signal for indicating a driving mode of the display device, and generate a gate clock signal and a gate control signal based on the mode selecting signal; and
a gate driver configured to generate a plurality of sensing line selecting signals corresponding to the plurality of regions based on the gate clock signal and the gate control signal, and generate a plurality of scan carry signals and a plurality of sensing carry signals corresponding to the plurality of regions based on the plurality of sensing line selecting signals,
wherein the gate driver provides the plurality of scan carry signals and the plurality of sensing carry signals to the at least one gate line during a blank period of a frame.

2. The display device of claim 1,
wherein each of the plurality of scan carry signals and the plurality of sensing carry signals includes a first scan carry signal and a first sensing carry signal respectively, and
wherein the gate driver generates the first scan carry signal and the first sensing carry signal, and outputs the first scan carry signal and the first sensing carry signal to the pixels included in a first region when a first sensing line selecting signal corresponding to the first region has an enable level.

3. The display device of claim 1,
wherein the gate driver includes:
a sensing line selecting signal generator configured to generate the plurality of sensing line selecting signals;
a clock signal generator configured to generate a plurality of scan carry clock signals, a plurality of sensing carry clock signals, and a plurality of carry clock signals based on the gate clock signal; and
a gate signal generator configured to generate the plurality of scan carry signals and the plurality of sensing carry signals based on the plurality of sensing line selecting signal, the plurality of scan carry clock signals, the plurality of sensing carry clock signals, and the plurality of carry clock signals.

4. The display device of claim 3,
wherein the gate signal generator includes:
a carry signal generator configured to generate a plurality of carry signals based on the plurality of carry clock signals;
a scan carry signal generator configured to generate the plurality of scan carry signals based on the plurality of scan carry clock signals and the plurality of carry signals; and
a sensing carry signal generator configured to generate the plurality of sensing carry signals based on the plurality of sensing carry clock signals and the plurality of carry signals.

5. The display device of claim 4,
wherein the gate signal generator includes a plurality of stages corresponding to the plurality of regions and including a first stage, the first stage receiving a first sensing line selecting signal and corresponding to a first region, and
wherein, when the first sensing line selecting signal has an enable level, the first stage outputs a first scan carry signal and a first sensing carry signal to the pixels included in the first region based on the first sensing line selecting signal.

6. The display device of claim 5,
wherein the first stage includes:
a scan selecting circuit configured to receive the first sensing line selecting signal, a transmitting signal, and a first carry signal corresponding to the first stage, and control a sensing control node based on the first sensing line selecting signal, the transmitting signal, and the first carry signal;
a sensing discharge circuit configured to receive a scan start signal, and control the sensing control node based on the scan start signal;
a sensing output circuit configured to receive a sensing carry clock signal among the plurality of sensing carry clock signals, and control a sensing output node based on the sensing carry clock signal; and
a scan output circuit configured to receive a scan carry clock signal among the plurality of scan carry clock signals, and control a scan output node based on the scan carry clock signal.

7. The display device of claim 6,
wherein the scan selecting circuit charges a sensing node when the first sensing line selecting signal has an enable level and the first carry signal has an enable level, and the scan selecting circuit transmits a voltage of the sensing node to the sensing control node when the transmitting signal has an enable level.

8. The display device of claim 7,
wherein the transmitting signal has the enable level during the blank period for which the display device displays no images.

9. The display device of claim 7,
wherein the sensing output circuit controls the sensing output node based on the voltage of the sensing control node when the sensing carry clock signal has an enable level.

10. The display device of claim 9,
wherein the sensing output circuit outputs the first sensing carry signal when the voltage of the sensing control node has a high level and the sensing carry clock signal has the enable level.

11. The display device of claim 7,
wherein the scan output circuit controls the scan output node based on the voltage of the sensing control node when the scan carry clock signal has an enable level.

12. The display device of claim 11,
wherein the scan output circuit outputs the first scan carry signal when the voltage of the sensing control node has a high level and the scan carry clock signal has the enable level.

13. The display device of claim 6,
wherein the sensing discharge circuit discharges the sensing control node when the scan start signal has an enable level.

14. The display device of claim 1,
wherein the driving mode includes a normal mode in which the display device is operated at a high frequency and a low electric power mode in which the display device is operated at a low frequency.

15. A gate driver comprising:
a sensing line selecting signal generator configured to receive a gate clock signal and a gate control signal, and generate a plurality of sensing line selecting signals corresponding to a plurality of regions based on the gate clock signal and the gate control signal, wherein each of the gate clock signal and the gate control signal is generated based on a mode selecting signal for indicating a driving mode of a display device, and each of the plurality of regions includes at least one gate line;
a clock signal generator configured to generate a plurality of scan carry clock signals, a plurality of sensing carry clock signals, and a plurality of carry clock signals based on the gate clock signal; and
a gate signal generator configured to generate a plurality of scan carry signals and a plurality of sensing carry signals based on the plurality of sensing line selecting signals, the plurality of scan carry clock signals, the plurality of sensing carry clock signals, and the plurality of carry clock signals, and provide the plurality of scan carry signals and the plurality of sensing carry signals to the at least one gate line during a blank period of a frame.

16. The gate driver of claim 15,
wherein the gate signal generator includes:
a carry signal generator configured to generate a plurality of carry signals based on the plurality of carry clock signals;
a scan carry signal generator configured to generate the plurality of scan carry signals based on the plurality of scan carry clock signals and the plurality of carry signals; and
a sensing carry signal generator configured to generate the plurality of sensing carry signals based on the plurality of sensing carry clock signals and the plurality of carry signals.

17. The gate driver of claim 16,
wherein the gate signal generator includes a plurality of stages corresponding to the plurality of regions and including a first stage, the first stage receiving a first sensing line selecting signal and corresponding to a first region, and
wherein, when the first sensing line selecting signal has an enable level, the first stage outputs a first scan carry signal and a first sensing carry signal to the pixels included in the first region based on the first sensing line selecting signal.

18. The gate driver of claim 17,
wherein the first stage includes:
a scan selecting circuit configured to receive the first sensing line selecting signal, a transmitting signal, and a first carry signal corresponding to the first stage, and control a sensing control node based on the first sensing line selecting signal, the transmitting signal, and the first carry signal;
a sensing discharge circuit configured to receive a scan start signal, and control the sensing control node based on the scan start signal;
a sensing output circuit configured to receive a sensing carry clock signal among the plurality of sensing carry clock signals, and control a sensing output node based on the sensing carry clock signal; and
a scan output circuit configured to receive a scan carry clock signal among the plurality of scan carry clock signals, and control a scan output node based on the scan carry clock signal.

19. An electronic device comprising:
a processor configured to generate a mode selecting signal for indicating a driving mode of a display device; and
a display module divided into a plurality of regions, each of the plurality regions including at least one gate line and a plurality of pixels connected to the at least one gate line,
wherein the display module is configured to generate a gate clock signal and a gate control signal based on the mode selecting signal, generate a plurality of sensing line selecting signals corresponding to the plurality of regions based on the gate clock signal and the gate control signal, generate a plurality of scan carry signals and a plurality of sensing carry signals corresponding to the plurality of regions based on the each of the plurality of sensing line selecting signals, and
wherein the display module provides the plurality of scan carry signals and the plurality of sensing carry signals to the at least one gate line during a blank period of a frame.

20. The electronic device of claim 19,
wherein each of the plurality of scan carry signals and the plurality of sensing carry signals includes a first scan carry signal and a first sensing carry signal respectively, and
wherein the display module generates the first scan carry signal and the first sensing carry signal, and outputs the first scan carry signal and the first sensing carry signal to the pixels included in a first region when a first sensing line selecting signal corresponding to the first region has an enable level.
